(19) United States
(12) Patent Application Publication
(10) Pub. No.: US 2019/0064413 A1
(43) Pub. Date: Feb. 28, 2019

(54) CIRCULARLY POLARIZING PLATE AND IMAGE DISPLAY DEVICE

(71) Applicant: ZEON CORPORATION, Chiyoda-ku, Tokyo (JP)

(72) Inventor: Takao KOBAYASHI, Tokyo (JP)

(73) Assignee: ZEON CORPORATION, Chiyoda-ku, Tokyo (JP)

(21) Appl. No.: 16/086,815

(22) PCT Filed: Mar. 27, 2017
(86) PCT No.: PCT/JP2017/012291

§ 371 Date: Sep. 20, 2018

(30) Foreign Application Priority Data
Mar. 30, 2016 (JP) 2016-067090

(51) Int. Cl. G02B 5/30; G02F 1/1335; H01L 51/50; H05B 33/02

(52) U.S. Cl. CPC G02B 5/305; G02F 1/133528; H01L 51/5056; H05B 33/02; G02B 5/3083; H01L 51/5012

(57) ABSTRACT

A circularly polarizing plate for disposing in an image display device including an image display element is disposed on a visually recognizing side of the image display element and includes a linear polarizer and a broadband λ/4 plate in this order from a side of the image display element. The broadband λ/4 plate includes a λ/2 plate and a λ/4 plate in this order from a side of the linear polarizer. At least one of the λ/2 plate and the λ/4 plate is a multilayer body including a first outer layer, an intermediate layer containing an ultraviolet absorber, and a second outer layer in this order. The broadband λ/4 plate has a light transmittance of 1.0% or less at a wavelength of 380 nm. The broadband λ/4 plate has a light transmittance of 5.0% or less at a wavelength of 390 nm.

### FIELD

The present invention relates to a circularly polarizing plate and an image display device.

### BACKGROUND

An image of an image display device is sometimes displayed by linearly polarized light. For example, since a liquid crystal display device includes a liquid crystal cell and a linear polarizer, an image of the liquid crystal display device may be displayed by the linearly polarized light having passed through the linear polarizer. As another example, on a screen of an organic electroluminescence display device (hereinafter, sometimes appropriately referred to as an “organic EL display device”), a circularly polarizing plate is sometimes disposed for suppressing the reflection of external light. The image of such an organic EL display device including a circularly polarizing plate may be displayed by the linearly polarized light having passed through a linear polarizer that the circularly polarizing plate includes.

The image displayed by the linearly polarized light as previously described sometimes becomes dark and cannot be visually recognized when viewed through polarized sunglasses. Specifically, when the vibration direction of linearly polarized light for displaying an image is parallel to the polarized light absorption axis of polarized sunglasses, the linearly polarized light cannot pass through the polarized sunglasses. Accordingly, the image cannot be visually recognized. Herein, the vibration direction of linearly polarized light means the vibration direction of the electric field of linearly polarized light.

In order that the image becomes visually recognizable, it is proposed to dispose a λ/4 plate on the visually recognizing side of a linear polarizer of an image display device (Patent Literatures 1 and 2). The linearly polarized light having passed through the linear polarizer is converted into circularly polarized light by the λ/4 plate. Since part of this circularly polarized light can pass through polarized sunglasses, the image can become visually recognizable through polarized sunglasses.

Also, the technologies disclosed in Patent Literatures 3 to 7 are known.

### CITATION LIST

### Patent Literature

Patent Literature 1: Japanese Patent Application Laid-Open No. Hei. 3-174512 A

Patent Literature 2: Japanese Patent Application Laid-Open No. 2005-352068 A

Patent Literature 3: Japanese Patent Application Laid-Open No. 2003-114325 A

Patent Literature 4: Japanese Patent Application Laid-Open No. Hei 11-183723

Patent Literature 5: Japanese Patent Application Laid-Open No. 2015-31753 A

Patent Literature 6: Japanese Patent Application Laid-Open No. 2015-45845 A

Patent Literature 7: Japanese Patent Application Laid-Open No. 2014-102440 A

### SUMMARY

### Technical Problem

According to the studies of the present inventor, it is desirable to use, as a λ/4 plate, a member capable of converting linearly polarized light into circularly polarized light in a wide wavelength band, for preventing the color of the image viewed through polarized sunglasses from changing by a slant of polarized sunglasses thereby to improve the visibility of the image. Therefore, the present inventor prepared a broadband λ/4 plate including a combination of a λ/4 plate and a λ/2 plate, and provided this broadband λ/4 plate to an image display device in an attempt to improve the visibility of the image viewed through polarized sunglasses. As a result, excellent visibility was achieved when the image display device was viewed in a front direction of the display surface thereof. However, the aforementioned broadband λ/4 plate was poor in light resistance and was colored when irradiated with light.

The present invention has been devised in view of the aforementioned problem. An object of the present invention is to provide: a circularly polarizing plate which includes a broadband λ/4 plate being excellent in light resistance and can improve the visibility of an image seen through polarized sunglasses; and an image display device including the circularly polarizing plate.

### Solution to Problem

The present inventor has extensively conducted research for solving the aforementioned problem. As a result, the present inventor has found that the aforementioned problem can be solved by a circularly polarizing plate including a linear polarizer, a λ/2 plate, and the λ/4 plate in this order, in which a multilayer body having an intermediate layer containing an ultraviolet absorber is adopted as at least one of the λ/2 plate and the λ/4 plate, and the light transmittance at a wavelength of 380 nm and the light transmittance at a wavelength of 390 nm of the broadband λ/4 plate containing the λ/2 plate and the λ/4 plate are within a specific range. Thus, the present invention has been accomplished.

That is, the present invention is as follows.

(1) A circularly polarizing plate for disposing in an image display device having an image display element, the circularly polarizing plate being disposed on a visually recognizing side of the image display element,

the circularly polarizing plate comprising a linear polarizer and a broadband λ/4 plate in this order from a side of the image display element, wherein

the broadband λ/4 plate includes a λ/2 plate and a λ/4 plate in this order from a side of the linear polarizer,

at least one of the λ/2 plate and the λ/4 plate is a multilayer body including a first outer layer, an intermediate layer containing an ultraviolet absorber, and a second outer layer in this order,

the broadband λ/4 plate has a light transmittance of 1.0% or less at a wavelength of 380 nm, and

the broadband λ/4 plate has a light transmittance of 5.0% or less at a wavelength of 390 nm.

(2) The circularly polarizing plate according to (1), wherein

the λ/2 plate has a thickness of 25 μm or more and 45 μm or less,

the λ/4 plate has a thickness of 10 μm or more and 60 μm or less, and

a total thickness of the λ/2 plate and the λ/4 plate is 100 μm or less.

(3) The circularly polarizing plate according to (1) or (2), wherein a ratio of “thickness of the intermediate layer”/“thickness of the multilayer body” is ⅓ to 80/82.

(4) The circularly polarizing plate according to any one of (1) to (3), wherein

the intermediate layer is formed of a thermoplastic resin containing the ultraviolet absorber, and

the thermoplastic resin contains the ultraviolet absorber in an amount of 3% by weight to 20% by weight.

(5) The circularly polarizing plate according to any one of (1) to (4), an angle formed by a slow axis of the λ/4 plate with respect to the polarized light absorption axis of the linear polarizer being (2α+45°)±5°,

wherein α is an angle formed by a slow axis of the λ/2 plate with respect to a polarized light absorption axis of the linear polarizer.

(6) The circularly polarizing plate according to any one of (1) to (5), wherein an angle α formed by the slow axis of the λ/2 plate with respect to the polarized light absorption axis of the linear polarizer is 15°±5°.

(7) The circularly polarizing plate according to any one of (1) to (6), wherein the λ/4 plate is an obliquely stretched film.

(8) The circularly polarizing plate according to any one of (1) to (7), wherein the λ/2 plate is a sequentially biaxially stretched film.

(9) An image display device comprising an image display element, and the circularly polarizing plate according to any one of (1) to (8), the circularly polarizing plate being disposed on the visually recognizing side of the image display element.

(10) The image display device according to (9), wherein the image display element is a liquid crystal cell or an organic electroluminescence element.

### Advantageous Effects of Invention

The present invention can provide a circularly polarizing plate which includes a broadband λ/4 plate being excellent in light resistance and can improve the visibility of an image seen through polarized sunglasses; and an image display device including the circularly polarizing plate.

### BRIEF DESCRIPTION OF DRAWINGS

FIG. 1 is a cross-sectional view schematically illustrating a circularly polarizing plate according to an embodiment of the present invention.

FIG. 2 is an exploded perspective view schematically illustrating a relationship of a linear polarizer, a λ/2 plate, and a λ/4 plate in the circularly polarizing plate as an example of the present invention.

FIG. 3 is a cross-sectional view schematically illustrating an example of a liquid crystal display device as an image display device according to an embodiment of the present invention.

FIG. 4 is a cross-sectional view schematically illustrating an example of an organic EL display device as an image display device according to an embodiment of the present invention.

### DESCRIPTION OF EMBODIMENTS

Hereinafter, the present invention will be described in detail with reference to embodiments and examples. However, the present invention is not limited to the following embodiments and examples, and may be freely modified for implementation without departing from the scope of claims of the present invention and the scope of their equivalents.

In the following description, a “long-length” film refers to a film with the length that is 5 times or more the width, and preferably a film with the length that is 10 times or more the width, and specifically refers to a film having a length that allows a film to be wound up into a rolled shape for storage or transportation. The upper limit of the length of the long-length film may be, but not particularly limited to, for example 100,000 times or less the width.

In the following description, an in-plane retardation Re of a film is a value represented by Re=(nx−ny)×d, unless otherwise specified. Herein, nx represents a refractive index in a direction in which the maximum refractive index is given among directions perpendicular to the thickness direction of the film (in-plane directions), ny represents a refractive index in a direction, among the above-mentioned in-plane directions of the film, orthogonal to the direction giving nx, and d represents the thickness of the film. The measurement wavelength of the retardation is 590 nm unless otherwise specified.

In the following description, a slow axis of a film refers to a slow axis in a surface of the film, unless otherwise specified.

In the following description, an oblique direction of a long-length film is a direction that is among in-plane direction of the film and neither parallel nor perpendicular to the widthwise direction of the film, unless otherwise specified.

In the following description, a front direction of a certain surface means a normal direction of the surface, and specifically, refers to a direction of a polar angle of 0° and an azimuth angle of 0° of the surface, unless otherwise specified.

In the following description, a direction of an element being “parallel”, “perpendicular”, and “orthogonal” may allow an error within the range of not impairing the advantageous effects of the present invention, for example, within a range of ±5°, unless otherwise specified.

In the following description, “polarizing plate”, “λ/2 plate”, “λ/4 plate”, and “positive C plate” include not only a rigid member but also a flexible member such as a resin film, unless otherwise specified.

In the following description, an angle formed by the optical axes (polarized light absorption axis, polarized light transmission axis, slow axis, etc.) of respective films in a member including a plurality of films represents an angle when the film is viewed from the thickness direction, unless otherwise specified.

[1. Summary]

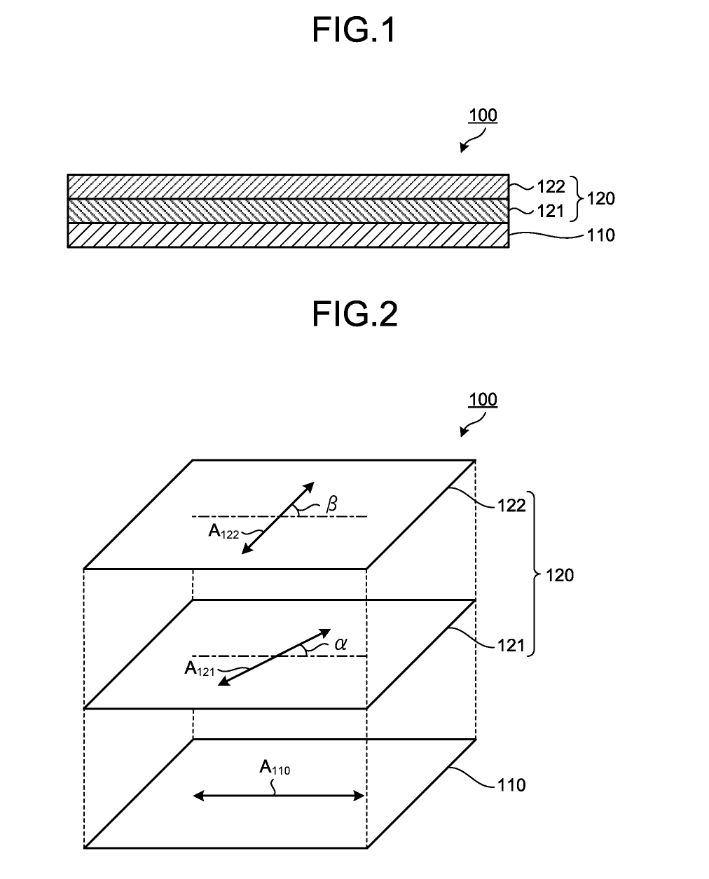

FIG. 1 is a cross-sectional view schematically illustrating a circularly polarizing plate according to an embodiment of the present invention.

As illustrated in FIG. 1, a circularly polarizing plate 100 includes a linear polarizer 110 and a broadband λ/4 plate 120 in this order. In an image display device (not illustrated) including an image display element, this circularly polarizing plate 100 is disposed on the visually recognizing side of the image display element. When the circularly polarizing plate 100 is disposed in the image display device, the circularly polarizing plate 100 is disposed such that the linear polarizer 110 and the broadband λ/4 plate 120 are stacked in this order from a side of the image display element. When the linear polarizer 110 and the broadband λ/4 plate 120 are combined in this manner, the image display device can display an image by circularly polarized light in a wide wavelength range. Therefore, the color of an image viewed through polarized sunglasses can be prevented from changing due to a slant of polarized sunglasses to improve the visibility of an image. Herein, the slant of polarized sunglasses refers to a slant in the direction in which polarized sunglasses rotate around a rotation axis perpendicular to the display surface of the image display device.

The broadband λ/4 plate 120 includes a λ/2 plate 121 and a λ/4 plate 122 in this order from a side of the linear polarizer 110. When the λ/2 plate 121 and the λ/4 plate 122 are combined in this manner, the broadband λ/4 plate 120 can exert a function as the λ/4 plate in a wide wavelength range.

Furthermore, at least one of the λ/2 plate 121 and the λ/4 plate 122 is a multilayer body including a first outer layer, an intermediate layer containing an ultraviolet absorber, and a second outer layer in this order. When the intermediate layer containing an ultraviolet absorber is provided in this manner, the light transmittance at a wavelength of 380 nm and the light transmittance at a wavelength of 390 nm of the broadband λ/4 plate are specific values or less. Thereby the broadband λ/4 plate 120 can obtain excellent light resistance. Accordingly, the coloring due to irradiation with light can be suppressed.

[2. Linear Polarizer]

The linear polarizer is an optical member having a polarized light transmission axis and a polarized light absorption axis, and is capable of absorbing linearly polarized light having a vibration direction parallel to the polarized light absorption axis and of transmitting linearly polarized light having a vibration direction parallel to the polarized light transmission axis. In the image display device including the circularly polarizing plate, the linearly polarized light having passed through this linear polarizer further passes through the broadband λ/4 plate including a combination of the λ/2 plate and the λ/4 plate to become circularly polarized light, and exits the image display device to be visually recognized as the light to display an image by an observer.

The linear polarizer for use may be a film obtained by giving appropriate treatments such as a dyeing treatment by iodine or a dichroic substance such as a dichroic dye, a stretching treatment, and a cross-linking treatment in an appropriate order by an appropriate procedure to a film of appropriate vinyl alcohol-based polymer such as polyvinyl alcohol and partially formalized polyvinyl alcohol. In a stretching treatment for producing a linear polarizer, a film is usually stretched in the lengthwise direction of the film. Therefore, the linear polarizer to be obtained may express a polarized light absorption axis parallel to the lengthwise direction of the linear polarizer and a polarized light transmission axis parallel to the widthwise direction of the linear polarizer. It is preferable that this linear polarizer has excellent polarization degree. The thickness of the linear polarizer is generally 5 μm to 80 μm, although not limited thereto.

The linear polarizer is usually obtained by producing a long-length film and cutting out this long-length film into a desired shape. In producing the long-length linear polarizer, the polarized light absorption axis of the linear polarizer is preferably parallel to the lengthwise direction of the linear polarizer. Thereby, in bonding a long-length λ/2 plate and a long-length λ/4 plate to produce a circularly polarizing plate, their optical axes can be aligned by disposing their lengthwise directions in parallel to each other. Consequently, the long-length linear polarizer, the long-length λ/2 plate, and the long-length λ/4 plate can be easily bonded by roll-to-roll method.

The bonding by roll-to-roll method refers to bonding in which the process of unwinding a film from a roll of a long-length film, conveying the unwound film, and bonding the film with another film on the conveyance line is performed, and the obtained bonded product is further wound up to obtain a roll. The bonding by roll-to-roll method eliminates the need for the complicated process of aligning optical axes, unlike bonding of films in a sheet piece shape. Therefore, efficient bonding can be achieved.

[3. Broadband λ/4 Plate]

The broadband λ/4 plate includes the λ/2 plate and the λ/4 plate in combination. This broadband λ/4 plate can exert the circularly polarized light conversion function of converting linearly polarized light having passed through the linear polarizer into circularly polarized light in a wide wavelength range. Therefore, when the image display device including the circularly polarizing plate containing this broadband λ/4 plate is viewed through polarized sunglasses, the visibility of an image can be improved.

Further, since this broadband λ/4 plate includes the multilayer body having the intermediate layer containing an ultraviolet absorber as at least one of the λ/2 plate and the λ/4 plate, the light transmittance in the ultraviolet region is low. Specifically, the light transmittance at a wavelength of 380 nm of the broadband λ/4 plate is usually 1.0% or less, preferably 0.8% or less, and more preferably 0.5% or less. The light transmittance at a wavelength of 390 nm of the broadband λ/4 plate is usually 5.0% or less, preferably 4.0% or less, and more preferably 3.0% or less.

Since the light transmittance at a wavelength of 380 nm and the light transmittance at a wavelength of 390 nm of the broadband λ/4 plate are as low as previously described, the broadband λ/4 plate can have improved light resistance. Consequently, the broadband λ/4 plate has low tendency to be colored even when irradiated with light.

In addition, since the UV transmittance of the broadband λ/4 plate is low in this manner, the deterioration of the linear polarizer by external light can be suppressed. Furthermore, when the circularly polarizing plate is provided to the image display device, the deterioration of the image display element by external light can be suppressed. Herein, external light encompasses not only natural light such as sunlight, but also artificial light such as ultraviolet light used in the production of the image display device.

The broadband λ/4 plate may further include an optional layer in combination with the λ/2 plate and the λ/4 plate. Examples of the optional layer may include a stickiness agent layer or an adhesive agent layer for bonding the λ/2 plate and the λ/4 plate.

[4. λ/2 Plate]

<4.1. Properties of λ/2 Plate>

The in-plane retardation of the λ/2 plate may be adequately set within the range in which the broadband λ/4 plate can be achieved by a combination of the λ/2 plate and the λ/4 plate. The specific in-plane retardation of the λ/2 plate is preferably 240 nm or more, and more preferably 250 nm or more, and is preferably 300 nm or less, more preferably 280 nm or less, and particularly preferably 265 nm or less. When the λ/2 plate has such an in-plane retardation, the combination of the λ/2 plate and the λ/4 plate can serve as the broadband λ/4 plate.

The λ/2 plate may have wavelength distribution property such as forward wavelength distribution property, flat wavelength distribution property, and reverse wavelength distribution property. The forward wavelength distribution property refer to wavelength distribution property in which the retardation becomes larger as the wavelength becomes shorter. The reverse wavelength distribution property refer to wavelength distribution property in which the retardation becomes smaller as the wavelength becomes shorter. The flat wavelength distribution property refer to wavelength distribution property in which the retardation does not change depending on the wavelength.

FIG. 2 is an exploded perspective view schematically illustrating a relationship of the linear polarizer 110, the λ/2 plate 121, and the λ/4 plate 122 in the circularly polarizing plate 100 as an example of the present invention. In FIG. 2, hypothetical lines parallel to a polarized light absorption axis A₁₁₀ of the linear polarizer 110 are indicated by dot-and-dash lines in the λ/2 plate 121 and the λ/4 plate 122.

As in the example illustrated in FIG. 2, an angle α formed by a slow axis A₁₂₁ of the λ/2 plate 121 with respect to a polarized light absorption axis A₁₁₀ of the linear polarizer 110 may be optionally set within the range in which the broadband λ/4 plate 120 can be achieved by the combination of the λ/2 plate 121 and the λ/4 plate 122. The specific range of the aforementioned angle α is preferably 15°±5°, more preferably 15°±3°, and particularly preferably 15°±1°. When the angle α falls within the aforementioned range, the broadband λ/4 plate 120 including the combination of the λ/2 plate 121 and the λ/4 plate 122 can stably convert the linearly polarized light in a wide wavelength range having passed through the linear polarizer 110 into circularly polarized light. Particularly in a case wherein the λ/2 plate 121 and the linear polarizer 110 both have a long-length shape, the angle α falls within the aforementioned range can result in facilitation of bonding of the λ/2 plate 121 and the linear polarizer 110 by roll-to-roll method.

The total light transmittance of the λ/2 plate is preferably 80% or more. The light transmittance may be measured in accordance with JIS K0115 using a spectrophotometer (ultraviolet-visible-near-infrared spectrophotometer “V-570” manufactured by JASCO Corporation).

The haze of the λ/2 plate is preferably 5% or less, more preferably 3% or less, particularly preferably 1% or less, and ideally 0%. As the haze, an average value calculated from haze values measured at five points by using a “turbidimeter NDH-300A” manufactured by Nippon Denshoku Industries Co., Ltd., in accordance with JIS K7361-1997 may be adopted.

The amount of volatile components contained in the λ/2 plate is preferably 0.1% by weight or less, more preferably 0.05% by weight or less, more preferably 0.02% by weight or less, and ideally zero. By reducing the amount of the volatile components, size stability of the λ/2 plate can be improved, and change in optical properties such as retardation with the lapse of time can be reduced.

Herein, the volatile component is a substance having a molecular weight of 200 or less contained in a small amount in the film. Examples thereof may include a residual monomer and a solvent. The amount of volatile components may be quantified by dissolving a film in chloroform and analyzing them by gas chromatography as the sum of substances with a molecular weight of 200 or less contained in the film.

The saturation water absorption ratio of the λ/2 plate is preferably 0.03% by weight or less, more preferably 0.02% by weight or less, particularly preferably 0.01% by weight or less, and ideally zero. When the saturation water absorption ratio of the λ/2 plate falls within the aforementioned range, change in optical characteristics such as in-plane retardation with the lapse of time can be reduced.

Herein, the saturation water absorption rate is a value expressed in percentage of a weight increased by immersing a film test piece in water at 23° C. for 24 times with respect to the weight of the film test piece before the immersion.

<4.2. Composition of λ/2 Plate>

The λ/2 plate is preferably a multilayer body including a first outer layer, an intermediate layer containing an ultraviolet absorber, and a second outer layer in this order. In this multilayer body, the first outer layer and the intermediate layer are usually in contact with each other without another layer interposed therebetween, and the intermediate layer and the second outer layer are usually in contact with each other without another layer interposed therebetween. Since this multilayer body includes the intermediate layer containing an ultraviolet absorber, the ultraviolet light passing through the multilayer body can be weakened. Furthermore, since this multilayer body includes the first outer layer and the second outer layer on respective sides of the intermediate layer, bleed-out of the ultraviolet absorber can be suppressed.

(Intermediate Layer)

The intermediate layer is usually formed of a resin containing a polymer and an ultraviolet absorber. As such a resin, it is preferable to use a thermoplastic resin. Therefore, the intermediate layer is preferably a layer of a thermoplastic resin containing a thermoplastic polymer and an ultraviolet absorber.

Examples of the thermoplastic polymer may include a polyolefin such as polyethylene and polypropylene; a polyester such as polyethylene terephthalate and polybutylene terephthalate; a polyarylene sulfide such as polyphenylene sulfide; a polyvinyl alcohol; a polycarbonate; a polyarylate; a cellulose ester polymer, a polyethersulfone; a polysulfone; a polyallylsulfone; a polyvinyl chloride; a polymer containing an alicyclic structure such as a norbornene polymer; and a rod-like liquid crystal polymer. As these polymers, one type thereof may be solely used, and two or more types thereof may also be used in combination at any ratio. The polymer may be a homopolymer or a copolymer. Among these, polymers containing an alicyclic structure are preferable because of their excellent mechanical properties, heat resistance, transparency, low hygroscopicity, size stability, and light weight properties.

The polymer containing an alicyclic structure is a polymer whose structural unit contains an alicyclic structure. The polymer containing an alicyclic structure may have an alicyclic structure in a main chain, an alicyclic structure in a side chain, or an alicyclic structure in a main chain and a side chain. Among these, a polymer containing an alicyclic structure in its main chain is preferable from the viewpoint of mechanical strength and heat resistance.

Examples of the alicyclic structure may include a saturated alicyclic hydrocarbon (cycloalkane) structure, and an unsaturated alicyclic hydrocarbon (cycloalkene, cycloalkyne) structure. Among these, a cycloalkane structure and a cycloalkene structure are preferable from the viewpoint of mechanical strength and heat resistance. A cycloalkane structure is particularly preferable among these.

The number of carbon atoms constituting the alicyclic structure is preferably 4 or more, and more preferably 5 or more, and is preferably 30 or less, more preferably 20 or less, and particularly preferably 15 or less, per alicyclic structure. When the number of carbon atoms constituting the alicyclic structure falls within this range, mechanical strength, heat resistance, and moldability of the resin including the polymer containing an alicyclic structure are highly balanced.

The ratio of the structural unit having an alicyclic structure in the polymer containing an alicyclic structure is preferably 55% by weight or more, more preferably 70% by weight or more, and particularly preferably 90% by weight or more. When the ratio of the structural unit having an alicyclic structure in the polymer containing an alicyclic structure falls within this range, the resin including the polymer containing an alicyclic structure has good transparency and heat resistance.

Examples of the polymer containing an alicyclic structure may include a norbornene-based polymer, a monocyclic olefin-based polymer, a cyclic conjugated diene-based polymer, a vinyl alicyclic hydrocarbon polymer, and hydrogenated products thereof. Among these, a norbornene-based polymer is more preferable because of good transparency and moldability.

Examples of the norbornene-based polymer may include a ring-opening polymer of a monomer having a norbornene structure and a hydrogenated product thereof; and an addition polymer of a monomer having a norbornene structure and a hydrogenated product thereof. Examples of the ring-opening polymer of a monomer having a norbornene structure may include a ring-opening homopolymer of one type of monomer having a norbornene structure, a ring-opening copolymer of two or more types of monomers having a norbornene structure, and a ring-opening copolymer of a monomer having a norbornene structure and an optional monomer copolymerizable therewith. Further, examples of the addition polymer of a monomer having a norbornene structure may include an addition homopolymer of one type of monomer having a norbornene structure, an addition copolymer of two or more types of monomers having a norbornene structure, and an addition copolymer of a monomer having a norbornene structure and an optional monomer copolymerizable therewith. Among these, a hydrogenated product of a ring-opening polymer of a monomer having a norbornene structure is particularly suitable from the viewpoint of moldability, heat resistance, low hygroscopicity, size stability, and light weight properties.

Examples of the monomer having a norbornene structure may include bicyclo[2.2.1]hept-2-ene (common name: norbornene), tricyclo[4.3.0.1^{2,5}]deca-3,7-diene (common name: dicyclopentadiene), 7,8-benzotricyclo[4.3.0.1^{2,5}]dec-3-ene (common name: methanotetrahydrofluorene), tetracyclo[4.4.0.1^{2,5}.1^{7,10}]dodec-3-ene (common name: tetracyclododecene), and derivatives of these compounds (for example, those with a substituent on the ring). Examples of the substituent may include an alkyl group, an alkylene group, and a polar group. These substituents may be the same as or different from each other, and a plurality of these substituents may be bonded to the ring. As the monomer having a norbornene structure, one type thereof may be solely used, and two or more types thereof may also be used in combination at any ratio.

Examples of the polar group may include a heteroatom, and an atomic group having a heteroatom. Examples of the heteroatom may include an oxygen atom, a nitrogen atom, a sulfur atom, a silicon atom, and a halogen atom. Specific examples of the polar group may include a carboxyl group, a carbonyloxycarbonyl group, an epoxy group, a hydroxyl group, an oxy group, an ester group, a silanol group, a silyl group, an amino group, a nitrile group, and a sulfonic acid group.

Examples of a monomer that is ring-opening copolymerizable with the monomer having a norbornene structure may include monocyclic olefins such as cyclohexene, cycloheptene, and cyclooctene, and derivatives thereof; and cyclic conjugated dienes such as cyclohexadiene and cycloheptadiene, and derivatives thereof. As the monomer that is ring-opening copolymerizable with the monomer having a norbornene structure, one type thereof may be solely used, and two or more types thereof may also be used in combination at any ratio.

The ring-opening polymer of the monomer having a norbornene structure may be produced, for example, by polymerizing or copolymerizing the monomer in the presence of a ring-opening polymerization catalyst.

Examples of the monomer that is addition copolymerizable with the monomer having a norbornene structure may include α-olefins of 2 to 20 carbon atoms such as ethylene, propylene, and 1-butene, and derivatives thereof; cycloolefins such as cyclobutene, cyclopentene, and cyclohexene, and derivatives thereof; and non-conjugated dienes such as 1,4-hexadiene, 4-methyl-1,4-hexadiene, and 5-methyl-1,4-hexadiene. Among these, α-olefin is preferable, and ethylene is more preferable. As the monomer that is addition copolymerizable with the monomer having a norbornene structure, one type thereof may be solely used, and two or more types thereof may also be used in combination at any ratio.

The addition polymer of the monomer having a norbornene structure may be produced, for example, by polymerizing or copolymerizing the monomer in the presence of an addition polymerization catalyst.

The above-mentioned hydrogenated products of the ring-opening polymer and the addition polymer may be produced, for example, by hydrogenating an unsaturated carbon-carbon bond, preferably 90% or more thereof, in a solution of the ring-opening polymer and the addition polymer in the presence of a hydrogenation catalyst containing a transition metal such as nickel, palladium, or the like.

Among the norbornene-based polymers, it is preferable that the polymer has an X: bicyclo[3.3.0]octane-2,4-diyl-ethylene structure and a Y: tricyclo[4.3.0.1^{2,5}]decane-7,9-diyl-ethylene structure as structural units, wherein the amount of these structural units is 90% by weight or more relative to the entire structural units of the norbornene-based polymer, and the content ratio of X and Y is 100:0 to 40:60 by weight ratio of X:Y. By using such a polymer, the layer containing the norbornene-based polymer can be made to have excellent stability of optical properties without size change over a long period of time.

The weight-average molecular weight (Mw) of the polymer contained in the intermediate layer is preferably 10,000 or more, more preferably 15,000 or more, and particularly preferably 20,000 or more, and is preferably 100,000 or less, more preferably 80,000 or less, and particularly preferably 50,000 or less. When the weight-average molecular weight falls within this range, mechanical strength and moldability of the resin are highly balanced.

The molecular weight distribution (Mw/Mn) of the polymer contained in the intermediate layer is preferably 1.2 or more, more preferably 1.5 or more, and particularly preferably 1.8 or more, and is preferably 3.5 or less, more preferably 3.0 or less, and particularly preferably 2.7 or less. Herein, Mn represents the number-average molecular weight. When the molecular weight distribution is equal to or more than the lower limit value of the aforementioned range, the productivity of the polymer can be increased and the production cost can be suppressed. When the molecular weight distribution is equal to or less than the upper limit value thereof, the amount of the low molecular weight component is small, and the relaxation at the time of high temperature exposure can be suppressed, whereby the stability of the layer containing the polymer can be enhanced.

The aforementioned weight-average molecular weight (Mw) and number-average molecular weight (Mn) may be measured as a polyisoprene- or polystyrene-equivalent weight-average molecular weight measured by gel permeation chromatography using cyclohexane as a solvent. When the sample is not dissolved in cyclohexane, toluene may be used as the solvent in the gel permeation chromatography.

The glass transition temperature of the polymer contained in the intermediate layer is preferably 100° C. or higher, more preferably 110° C. or higher, and particularly preferably 120° C. or higher, and is preferably 160° C. or lower, more preferably 150° C. or lower, and particularly preferably 140° C. or lower. When the glass transition temperature of the polymer is equal to or higher than the lower limit value of the aforementioned range, durability of the multilayer body in a high temperature environment can be increased. When the glass transition temperature thereof is equal to or lower than the upper limit value of the aforementioned range, stretching treatment is facilitated.

The absolute value of the photoelastic coefficient of the polymer contained in the intermediate layer is 10×10⁻¹² Pa⁻¹ or less, more preferably 7×10⁻¹² Pa⁻¹ or less, and particularly preferably 4×10⁻¹² Pa⁻¹ or less. Thereby fluctuation in retardation of the multilayer body can be reduced. Herein, the photoelastic coefficient C is a value represented by C=Δn/σ where Δn represents a birefringence and σ represents a stress.

The amount of the polymer in the resin contained in the intermediate layer is preferably 80.0% by weight or more, more preferably 82.0% by weight or more, and particularly preferably 84.0% by weight or more, and is preferably 97.0% by weight or less, more preferably 96.0% by weight or less, and particularly preferably 95.0% by weight or less. When the amount of the polymer falls within the aforementioned range, heat resistance and transparency of the multilayer body can be enhanced.

As the ultraviolet absorber, a compound capable of absorbing ultraviolet light may be used. By using an ultraviolet absorber, it is possible to impart the ability to prevent the transmission of ultraviolet light to the multilayer body including the intermediate layer. As the ultraviolet absorber, an organic ultraviolet absorber is preferable, and examples thereof may include organic ultraviolet absorbers such as a triazine-based ultraviolet absorber, a benzophenone-based ultraviolet absorber, a benzotriazole-based ultraviolet absorber, an acrylonitrile-based ultraviolet absorber, a salicylate-based ultraviolet absorber, a cyanoacrylate-based ultraviolet absorber, an azomethine-based ultraviolet absorber, an indole-based ultraviolet absorber, a naphthalimide-based ultraviolet absorber, and a phthalocyanine-based ultraviolet absorber.

As the triazine-based ultraviolet absorber, for example, a compound having a 1,3,5-triazine ring is preferable. Specific examples of the triazine-based ultraviolet absorber may include 2-(4,6-diphenyl-1,3,5-triazine-2-yl)-5-[(hexyl)oxy]-phenol, and 2,4-bis(2-hydroxy-4-butoxyphenyl)-6-(2,4-dibutoxyphenyl)-1,3,5-triazine. Examples of commercially available products of such triazine-based ultraviolet absorbers may include “TINUVIN 1577” manufactured by Ciba Specialty Chemicals, Inc., and “LA-F70” and “LA-46” manufactured by ADEKA Corporation.

Examples of the benzotriazole-based ultraviolet absorber may include 2,2′-methylenebis[4-(1,1,3,3-tetramethylbutyl)-6-(2H-benzotriazole-2-yl)phenol], 2-(3,5-di-di-tert-butyl-2-hydroxyphenyl)-5-chlorobenzotriazole, 2-(2H-benzotriazole-2-yl)-p-cresol, 2-(2H-benzotriazole-2-yl)-4,6-bis(1-methyl-1-phenylethyl)phenol, 2-benzotriazol-2-yl-4,6-di-tert-butylphenol, 2-[5-chloro(2H)-benzotriazol-2-yl)-4-methyl-6-(tert-butyl)phenol, 2-(2H-benzotriazol-2-yl)-4,6-di-tert-butylphenol, 2-(2H-benzotriazol-2-yl)-4-(1,1,3,3-tetramethylbutyl)phenol, 2-(2H-benzotriazol-2-yl)-4-methyl-6-(3,4,5,6-tetrahydrophthalimidylmethyl)phenol, reaction products of methyl 3-(3-(2H-benzotriazol-2-yl)-5-tert-butyl-4-hydroxyphenyl)propionate/polyethylene glycol 300, and 2-(2H-benzotriazol-2-yl)-6-(linear and side chain dodecyl)-4-methylphenol. Examples of commercially available products of such triazole-based ultraviolet absorbers may include “Adekastab LA-31” manufactured by ADEKA Corporation, and “TINUVIN 328” manufactured by Ciba Specialty Chemicals Inc.

Examples of the azomethine-based ultraviolet absorber may include materials described in Japanese Patent No. 3366697 B, and examples of commercially available products may include “BONASORB UA-3701” manufactured by Orient Chemical Industries Co., Ltd.

Examples of the indole-based ultraviolet absorber may include materials described in Japanese Patent No. 2846091 B, and examples of commercially available products may include “BONASORB UA-3911” and “BONASORB UA-3912” manufactured by Orient Chemical Industries Co., Ltd.

Examples of the phthalocyanine-based ultraviolet absorber may include materials described in Japanese Patent No. 4403257 B and No. 3286905 B, and examples of commercially available products may include “FDB001” and “FDB002” manufactured by Yamada Chemical Co., Ltd.

Among these, from the viewpoint of excellent ultraviolet absorption performance in the vicinity of 380 nm, a triazine-based ultraviolet absorber, an azomethine-based ultraviolet absorber, and an indole-based ultraviolet absorber are preferable, and a triazine-based ultraviolet absorber is particularly preferable.

As the ultraviolet absorber, one type thereof may be solely used, and two or more types thereof may also be used in combination at any ratio.

The amount of the ultraviolet absorber in the resin contained in the intermediate layer is preferably 3% by weight or more, more preferably 4% by weight or more, and particularly preferably 5% by weight or more, and is preferably 20% by weight or less, more preferably 18% by weight or less, and particularly preferably 16% by weight or less. When the amount of the ultraviolet absorber is equal to or more than the lower limit value of the aforementioned range, the ability of the multilayer body to prevent the transmission of ultraviolet light can be particularly enhanced. When the amount of the ultraviolet absorber is equal to or less than the upper limit value of the aforementioned range, the transparency of the multilayer body for visible light can be enhanced.

The resin included in the intermediate layer may further contain an optional component in combination with the polymer and the ultraviolet absorber. Example of the optional component may include a colorant such as a pigment and a dye; a plasticizer; a fluorescent brightener; a dispersant; a thermal stabilizer; a light stabilizer; an antistatic agent; an antioxidant; and a surfactant. One type of these may be solely used, and two or more types thereof may also be used in combination at any ratio.

The method for producing the resin contained in the intermediate layer may be any method. The resin may be produced by mixing a polymer, an ultraviolet absorber, and optional components as necessary. Usually, the resin is produced by kneading a polymer and an ultraviolet absorber at a temperature at which the polymer can be melted. For kneading, a biaxial extruder may be used, for example.

The thickness of the intermediate layer is preferably set so that the ratio represented by “the thickness of the intermediate layer”/“the thickness of the multilayer body” falls within a specific range. The specific range is preferably ⅕ or more, more preferably ¼ or more, and particularly preferably ⅓ or more, and is preferably 80/82 or less, more preferably 79/82 or less, and particularly preferably 78/82 or less. When the ratio is equal to or more than the lower limit value of the aforementioned range, the ability of the multilayer body to prevent the transmission of ultraviolet light can be particularly enhanced. When the ratio is equal to or less than the upper limit value of the aforementioned range, the thickness of the multilayer body can be reduced.

(First Outer Layer)

The first outer layer is usually formed of a resin containing a polymer. As such a resin, it is preferable to use a thermoplastic resin. Therefore, the first outer layer is preferably a layer of a thermoplastic resin containing a thermoplastic polymer.

As the polymer contained in the resin included in the first outer layer, any polymer selected from the range described as the polymer contained in the resin included in the intermediate layer may be used. Thereby the same advantages as those described in the description of the intermediate layer can be obtained. In particular, as the polymer contained in the resin included in the first outer layer, it is preferable to use the same polymer as the polymer contained in the resin included in the intermediate layer. Thereby it becomes easy to increase the adhesion strength between the intermediate layer and the first outer layer and to suppress reflection of light at the interface between the intermediate layer and the first outer layer.

The amount of the polymer in the resin included in the first outer layer is preferably 90.0% by weight to 100% by weight, and more preferably 95.0% by weight to 100% by weight. When the amount of the polymer falls within the aforementioned range, the multilayer body can have sufficient heat resistance and transparency.

The resin included in the first outer layer may include an ultraviolet absorber, but it is preferable that the amount of the ultraviolet absorber in the resin included in the first outer layer is small, and it is more preferable that the resin included in the first outer layer does not contain an ultraviolet absorber. Since the resin included in the first outer layer does not contain an ultraviolet absorber, bleed-out of the ultraviolet absorber can be effectively suppressed.

The resin included in the first outer layer may further contain an optional component in combination with the polymer. Examples of the optional component may include components similar to those exemplified as optional components that may be contained in the resin included in the intermediate layer. As these components, one type thereof may be solely used, and two or more types thereof may also be used in combination at any ratio.

The thickness of the first outer layer is preferably set so that the ratio represented by “the thickness of the first outer layer”/“the thickness of the multilayer body” falls within a specific range. The specific range is preferably 1/82 or more, more preferably 2/82 or more, and particularly preferably 3/82 or more, and is preferably ⅓ or less, more preferably ¼ or less, and particularly preferably ⅕ or less. When the ratio is equal to or more than the lower limit value of the aforementioned range, bleed-out of the ultraviolet absorber contained in the intermediate layer can be effectively prevented. When the ratio is equal to or less than the upper limit value of the aforementioned range, the thickness of the multilayer body can be reduced.

(Second Outer Layer)

The second outer layer is usually formed of a resin containing a polymer. As the resin included in the second outer layer, any resin selected from the range of the resins described as the resin included in the first outer layer may be used. Thereby the same advantages as those described in the description of the first outer layer also to the second outer layer can be obtained.

The resin included in the first outer layer and the resin included in the second outer layer may be different resins, but are preferably the same resin. Particularly, when the resin included in the first outer layer and the resin included in the second outer layer are the same resin, the production cost of the multilayer body can be suppressed, and curling of the multilayer body can be suppressed.

The thickness of the second outer layer may be set to any thickness selected from the range described for the thickness of the first outer layer. Thereby the same advantages as those described in the description of the thickness of the first outer layer can be obtained. In particular, in order to suppress curling of the multilayer body, it is preferable that the thickness of the second outer layer is the same as that of the first outer layer.

[4.3. Thickness of λ/2 Plate]

The thickness of the λ/2 plate is preferably 25 μm or more, more preferably 27 μm or more, and particularly preferably 30 μm or more, and is preferably 45 μm or less, more preferably 43 μm or less, and particularly preferably 40 μm or less. When the thickness of the λ/2 plate is equal to or more than the lower limit value of the aforementioned range, desired retardation can be exhibited. When the thickness is equal to or less than the upper limit value of the aforementioned range, the thickness of the λ/2 plate can be reduced.

[4.4. Method for Producing λ/2 Plate]

The method for producing the λ/2 plate may be any method. The λ/2 plate may be produced as an obliquely stretched film by a production method including, for example, subjecting a long-length pre-stretch film formed of a resin to oblique stretching one or more times. Herein, “oblique stretching” means stretching a long-length film in an oblique direction. According to the production method including the oblique stretching, the λ/2 plate can be easily produced.

Further, it is preferable that the λ/2 plate is produced as a sequentially biaxially stretched film by a production method including further subjecting a film to longitudinal stretching after the oblique stretching. Herein, “longitudinal stretching” means stretching of a long-length film in the lengthwise direction thereof. According to the combination of oblique stretching and longitudinal stretching, a λ/2 plate capable of being bonded to a linear polarizer by a roll-to-roll method can be easily produced.

When the λ/2 plate is produced as a multilayer body including the intermediate layer, the first outer layer, and the second outer layer, it is preferable to use as the pre-stretch film a film having a multilayer structure including layers corresponding to the intermediate layer, the first outer layer, and the second outer layer.

Hereinafter, an example of a preferable method for producing the λ/2 plate will be described. The method for producing the λ/2 plate according to this example includes (a) a first step of preparing a long-length pre-stretch film including layers corresponding to the intermediate layer, the first outer layer, and the second outer layer, respectively, (b) a second step of stretching the long-length pre-stretch film in an oblique direction to obtain a long-length intermediate film, and (c) a third step of performing free uniaxial stretching of the intermediate film in a lengthwise direction to obtain a long-length λ/2 plate.

In the first step (a), a long-length pre-stretch film is prepared. The pre-stretch film may be produced by, for example, a production method including a step of molding a resin for forming the intermediate layer, a resin for forming the first outer layer, and a resin for forming the second outer layer into a film shape. Examples of the method for molding the resin may include a co-extrusion method and a co-casting method. Among these molding methods, a co-extrusion method is preferable because it is excellent in production efficiency and it has low tendency to leave volatile components in the film.

The production method using the co-extrusion method includes a step of co-extruding a resin. In the co-extrusion method, the resin is extruded in a form of layers in a melted state, to thereby form a layer of the resin for forming the first outer layer, a layer of the resin for forming the intermediate layer, and a layer of the resin for forming the second outer layer. In this case, examples of the extrusion method of the resin may include a co-extrusion T die method, a co-extrusion inflation method, and a co-extrusion lamination method. Among these, a co-extrusion T die method is preferable. The co-extrusion T die method includes a feed block method and a multi-manifold method, and a multi-manifold method is particularly preferable in that fluctuation in thickness can be reduced.

In the co-extrusion method, the melt temperature of the resin to be extruded is preferably (Tg+80° C.) or higher, and more preferably (Tg+100° C.) or higher, and is preferably (Tg+180° C.) or lower, and more preferably (Tg+150° C.) or lower. Herein, “Tg” represents the highest temperature of the glass transition temperatures of the polymers contained in the resins to be extruded. The above-mentioned melting temperature represents, for example in the co-extrusion T die method, the melting temperature of the resin in the extruder having the T die. When the melting temperature of the resin to be extruded is equal to or higher than the lower limit value of the aforementioned range, the fluidity of the resin can be sufficiently enhanced to improve the moldability. When the melting temperature is equal to or lower than the upper limit value, degradation of the resin can be suppressed.

The extrusion temperature may be adequately selected depending on the resin. For example, the temperature of the resin in the extruder may be set to Tg to (Tg+100° C.) at the resin inlet and to (Tg+50° C.) to (Tg+170° C.) at the resin outlet, and the die temperature is (Tg+50° C.) to (Tg+170° C.).

Furthermore, the arithmetic average roughness Ra of the die lip of the die is preferably 0 μm to 1.0 μm, more preferably 0 μm to 0.7 μm, and particularly preferably 0 μm to 0.5 μm. When the arithmetic average roughness of the die lip falls within the aforementioned range, it becomes easy to suppress streak-like defects of the pre-stretch film.

In the co-extrusion method, usually, a film-shaped melted resin extruded from a die lip is brought into close contact with a cooling roll to be cooled and cured. In this case, examples of the method for bringing the melted resin into close contact with a cooling roll may include an air knife method, a vacuum box method, and an electrostatic adhesion method.

By molding the resin into a film shape as described above, a long-length pre-stretch film including a layer of a resin for forming the first outer layer, a layer of a resin for forming the intermediate layer, and a layer of a resin for forming the second outer layer in this order is obtained.

After the long-length pre-stretch film is prepared in the first step (a), the second step (b) of stretching the long-length pre-stretch film in an oblique direction to obtain the intermediate film is performed. In the second step, stretching is usually performed using a tenter stretching machine while the pre-stretch film is continuously conveyed in the lengthwise direction. The tenter stretching machine has a plurality of grippers each capable of gripping both ends in the widthwise direction of the pre-stretch film. When the pre-stretch film is stretched by the grippers in a specific direction, stretching in any direction can be achieved.

The stretching ratio in the second step (b) is preferably 1.1 times or more, more preferably 1.15 times or more, and particularly preferably 1.2 times or more, and is preferably 5.0 times or less, more preferably 4.0 times or less, and particularly preferably 3.5 times or less. When the stretching ratio in the second step (b) is equal to or more than the lower limit value of the aforementioned range, occurrence of wrinkles on the λ/2 plate can be suppressed and the refractive index in the stretching direction can be increased. When the stretching ratio is equal to or less than the upper limit value of the aforementioned range, fluctuation of orientation angle of the λ/2 plate can be reduced and the slow axis direction can be easily controlled. Herein, the orientation angle refers to an angle formed by the slow axis of the film with respect to a certain reference direction. The orientation angle may be measured by a polarization microscope or Axoscan (manufactured by Axometrics, Inc.).

The stretching temperature in the second step (b) is preferably (Tg−5° C.) or higher, more preferably (Tg−2° C.) or higher, and particularly preferably Tg° C. or higher, and is preferably (Tg+40° C.) or lower, more preferably (Tg+35° C.) or lower, and particularly preferably (Tg+30° C.) or lower. When the stretching temperature in the second step (b) falls within the aforementioned range, molecules contained in the pre-stretch film can be reliably oriented. Therefore, an intermediate film having desired optical properties can be easily obtained.

By stretching in the second step (b), the molecules contained in the intermediate film are oriented. Therefore, the intermediate film has a slow axis. In the second step (b), stretching is performed in the oblique direction. Therefore, the slow axis of the intermediate film is expressed in the oblique direction of the intermediate film. Specifically, the intermediate film usually has a slow axis within a range of 5° to 85° with respect to the lengthwise direction of the intermediate film.

It is preferable that a specific direction of the slow axis of the intermediate film is set depending on the direction of the slow axis of a λ/2 plate desired to be produced. The orientation angle formed by the slow axis of the λ/2 plate obtained in the third step (c) with respect to the lengthwise direction thereof is usually smaller than the orientation angle formed by the slow axis of the intermediate film with respect to the lengthwise direction thereof. Therefore, it is preferable that the orientation angle formed by the slow axis of the intermediate film with respect to the lengthwise direction thereof is larger than the orientation angle formed by the slow axis of the λ/2 plate with respect to the lengthwise direction thereof.

After the second step (b), the third step (c) of performing free uniaxial stretching of the intermediate film in the lengthwise direction to obtain the long-length λ/2 plate is performed. Herein, free uniaxial stretching means stretching in a certain direction in which a restraining force is not applied in directions other than a stretching direction. Therefore, the free uniaxial stretching in the lengthwise direction of the intermediate film shown in this example refers to the stretching in the lengthwise direction which is performed without restricting the end portion in the widthwise direction of the intermediate film. Such stretching in the third step (c) is usually performed by a roll stretching machine while the intermediate film is continuously conveyed in the lengthwise direction.

It is preferable that the stretching ratio in the third step (c) is smaller than the stretching ratio in the second step (b). Thereby stretching can be performed for the λ/2 plate having a slow axis in the oblique direction while occurrence of wrinkles is suppressed. When stretching in the oblique direction and free uniaxial stretching in the lengthwise direction are performed in this order and the stretching ratio in the third step (c) is made smaller than the stretching ratio in the second step (b), a λ/2 plate having a slow axis in a direction in which the angle relative to the lengthwise direction is small can be easily produced.

Specifically, the stretching ratio in the third step (c) is preferably 1.1 times or more, more preferably 1.15 times or more, and particularly preferably 1.2 times or more, and is preferably 3.0 times or less, more preferably 2.8 times or less, and particularly preferably 2.6 times or less. When the stretching ratio in the third step (c) is equal to or more than the lower limit value of the aforementioned range, occurrence of wrinkles on the λ/2 plate can be suppressed. When the stretching ratio is equal to or less than the upper limit value of the aforementioned range, the slow axis direction can be easily controlled.

The stretching temperature T2 in the third step (c) is preferably higher than “T1−20° C.”, more preferably “T1−18° C.” or higher, and particularly preferably “T1−16° C.” or higher, and is preferably lower than “T1+20° C.”, more preferably “T1+18° C.” or lower, and particularly preferably “T1+16° C.” or lower, on the basis of the stretching temperature T1 in the second step (b). When the stretching temperature T2 in the third step (c) falls within the aforementioned range, the in-plane retardation of the λ/2 plate can be effectively adjusted.

The method for producing the λ/2 plate shown in the example may be performed with modification.

For example, the method for producing the λ/2 plate may further include an optional step, in addition to the first step (a), the second step (b), and the third step (c). Examples of the optional step may include a step of trimming both ends of the λ/2 plate, a step of providing a protective layer on the surface of the λ/2 plate, and a step of performing a surface treatment such as a chemical treatment and a physical treatment on the surface of the λ/2 plate.

For example, a film obtained by stretching a pre-stretch film in an optional direction may be used as the pre-stretch film. Examples of the method for performing such stretching of the pre-stretch film before the second step (b) may include a longitudinal stretching method of a roll process or float process, and a transversal stretching method using a tenter stretching machine.

[5. λ/4 Plate]

<5.1. Properties of λ/4 Plate>

The in-plane retardation of the λ/4 plate may be adequately set within the range in which the broadband λ/4 plate can be achieved by the combination of the λ/2 plate and the λ/4 plate. The specific in-plane retardation of the λ/4 plate is preferably 110 nm or more, and more preferably 118 nm or more, and is preferably 154 nm or less, more preferably 138 nm or less, and particularly preferably 128 nm or less. When the λ/4 plate has such an in-plane retardation, the combination of the λ/2 plate and the λ/4 plate can serve as the broadband λ/4 plate.

The λ/4 plate may have wavelength distribution property such as forward wavelength distribution property, flat wavelength distribution property, and reverse wavelength distribution property.

In general, when the multilayer film including a combination of the λ/4 plate having an angle θ_{λ/4} with respect to a given reference direction and the λ/2 plate having an angle θ_{λ/2} with respect to the given reference direction satisfies the formula C: “θ_{λ/4}=2θ_{λ/2}+45°”, this multilayer film becomes a broadband λ/4 plate which can provide the light passing through the multilayer film with an in-plane retardation of approximately ¼ wavelength of the wavelength of the light in a wide wavelength range (see Japanese Patent Application Laid-Open No. 2007-004120 A).

Therefore, as illustrated in FIG. 2, from the viewpoint of exerting the function of the broadband λ/4 plate 120 by the combination of the λ/2 plate 121 and the λ/4 plate 122, the slow axis A₁₂₂ of the λ/4 plate 122 preferably satisfies, with the slow axis A₁₂₁ of the λ/2 plate 121, a relationship close to the relationship represented by the aforementioned formula C. Specifically, an angle β formed by the slow axis A₁₂₂ of the λ/4 plate 122 with respect to the polarized light absorption axis A₁₁₀ of the linear polarizer 110 is preferably (2α+45°)±5°, more preferably (2α+45°)±3°, and particularly preferably (2α+45°)±1°. Herein, an angle α represents an angle formed by the slow axis A₁₂₁ of the λ/2 plate 121 with respect to the polarized light absorption axis A₁₁₀ of the linear polarizer 110.

The rotating direction in which the slow axis A₁₂₂ of the λ/4 plate 122 forms the angle β with respect to the polarized light absorption axis A₁₁₀ of the linear polarizer 110 is usually the same as the rotating direction in which the slow axis A₁₂₁ of the λ/2 plate 121 forms the angle α with respect to the polarized light absorption axis A₁₁₀ of the linear polarizer 110. Therefore, for example, when seen from the thickness direction, if the slow axis A₁₂₁ of the λ/2 plate 121 forms the angle α with respect to polarized light absorption axis A₁₁₀ of the linear polarizer 110 in a clockwise rotation, the slow axis A122 of the λ/4 plate 122 usually forms the angle β with respect to polarized light absorption axis A₁₁₀ of the linear polarizer 110 in a clockwise rotation. As another example, when seen from the thickness direction, if the slow axis A₁₂₁ of the λ/2 plate 121 forms the angle α with respect to polarized light absorption axis A₁₁₀ of the linear polarizer 110 in a counterclockwise rotation, the slow axis A₁₂₂ of the λ/4 plate 122 usually forms the angle β with respect to polarized light absorption axis A₁₁₀ of the linear polarizer 110 in a counterclockwise rotation.

The total light transmittance of the λ/4 plate is preferably 80% or more.

The haze of the λ/4 plate is preferably 5% or less, more preferably 3% or less, particularly preferably 1% or less, and ideally 0%.

The amount of volatile components contained in the λ/4 plate is preferably 0.1% by weight or less, more preferably 0.05% by weight or less, further preferably 0.02% by weight or less, and ideally 0. By reducing the amount of the volatile components, the size stability of the λ/4 plate can be improved and change in optical properties such as retardation with the lapse of time can be reduced.

The saturated water absorption ratio of the λ/4 plate is preferably 0.03% by weight or less, more preferably 0.02% by weight or less, particularly preferably 0.01% by weight or less, and ideally 0. When the saturated water absorption ratio of the λ/4 plate falls within the aforementioned range, change in optical properties such as in-plane retardation with the lapse of time can be reduced.

[5.2. Composition of λ/4 Plate]

The λ/4 plate is preferably a resin film formed of a resin, and in particular, is more preferably a multilayer body including, in this order, a first outer layer, an intermediate layer containing an ultraviolet absorber, and a second outer layer. As the multilayer body applicable to the λ/4 plate, any multilayer body selected from the range described as the multilayer body applicable to the λ/2 plate may be used. Therefore, the same matters as those described in the description of the multilayer body applicable to the λ/2 plate can be optionally adopted for the resin contained in the intermediate layer, the resin contained in the first outer layer, the resin contained in the second outer layer, the ratio represented by “thickness of the intermediate layer”/“thickness of the multilayer body”, and the like as to the multilayer body as the λ/4 plate. Thereby the same advantages as those described in the description of the λ/2 plate can also be obtained for the λ/4 plate.

[5.3. Thickness of λ/4 Plate]

The thickness of the λ/4 plate is preferably 10 μm or more, more preferably 13 μm or more, and particularly preferably 15 μm or more, and is preferably 60 μm or less, more preferably 58 μm or less, and particularly preferably 55 μm or less. When the thickness of the λ/4 plate is equal to or more than the lower limit value of the aforementioned range, a desired retardation can be easily exerted. When the thickness is equal to or less than the upper limit value of the aforementioned range, the thickness of the film can be reduced.

The total thickness of the λ/2 plate and the λ/4 plate is preferably set to a specific thickness or less. The specific total thickness is preferably 100 μm or less, more preferably 85 μm or less, and particularly preferably 70 μm or less. When the total thickness of the λ/2 plate and the λ/4 plate is set to be thin in this manner, the thickness of the image display device can be reduced. There is no specific lower limit of the total thickness, but it is preferably 35 μm or more, more preferably 40 μm or more, and particularly preferably 45 μm or more from the viewpoint of facilitating the production of the broadband λ/4 plate with desired properties.

[5.1. Method for Producing λ/4 Plate]

The method for producing the λ/4 plate may be any method. For example, the λ/4 plate may be produced as a stretched film by a production method including stretching a long-length pre-stretch film formed of a resin. In particular, it is preferable that the λ/4 plate is produced as an obliquely stretched film by a production method including subjecting a long-length pre-stretch film to oblique stretching one or more times. According to the production method including the oblique stretching, the λ/4 plate can be easily produced. When the λ/4 plate is produced as a multilayer body including an intermediate layer, a first outer layer, and a second outer layer, it is preferable to use as the pre-stretch film a film with a multilayer structure including layers corresponding to the intermediate layer, the first outer layer, and the second outer layer.

Hereinafter, an example of a preferable method for producing the λ/4 plate will be described. The method for producing the λ/4 plate according to this example includes (d) a fourth step of preparing a long-length pre-stretch film including layers corresponding to the intermediate layer, the first outer layer, and the second outer layer, respectively, and (e) a fifth step of stretching the long-length pre-stretch film to obtain a long-length λ/4 plate.

In the fourth step (d), a long-length pre-stretch film is prepared. The pre-stretch film may be produced, for example, by a method that is the same as the first step (a) in the method for producing the λ/2 plate. In the fourth step (d), when the pre-stretch film is produced by the same method as in the first step (a), the same advantages as in the first step (a) are obtained also in the fourth step (d).

After the long-length pre-stretch film is prepared in the fourth step (d), the fifth step (e) is performed in which the long-length pre-stretch film is stretched to obtain the λ/4 plate. In the fifth step, stretching is usually performed while the pre-stretch film is continuously conveyed in the lengthwise direction. In this case, the stretching direction may be a lengthwise direction or a widthwise direction of the film, but it is preferable that the stretching direction is an oblique direction. The stretching may be free uniaxial stretching in which no restraining force is applied in directions other than the stretching direction, or may be stretching in which a restraining force is also applied in directions other than the stretching direction. The stretching may be performed using any stretching machine, such as a roll stretching machine and a tenter stretching machine.

The stretching ratio in the fifth step (e) is preferably 1.1 times or more, more preferably 1.15 times or more, and particularly preferably 1.2 times or more, and is preferably 3.0 times or less, more preferably 2.8 times or less, and particularly preferably 2.6 times or less. When the stretching ratio in the fifth step (e) is equal to or more than the lower limit value of the aforementioned range, the refractive index in the stretching direction can be increased. When the stretching ratio is equal to or less than the upper limit value, the slow axis direction of the λ/4 plate can be easily controlled.

The stretching temperature in the fifth step (e) is preferably (Tg−5° C.) or higher, more preferably (Tg−2° C.) or higher, and particularly preferably Tg° C. or higher, and is preferably (Tg+40° C.) or lower, more preferably (Tg+35° C.) or lower, and particularly preferably (Tg+30° C.) or lower. When the stretching temperature in the fifth step (e) falls within the aforementioned range, molecules contained in the pre-stretch film can be reliably oriented. Therefore, a λ/4 plate having desired optical properties can be easily obtained.

The method for producing the λ/4 plate shown in the example may be performed with modification. For example, the method for producing the λ/4 plate may also include an optional step, in addition to the fourth step (d) and the fifth step (e). For example, the method for producing the λ/4 plate may also include a step of trimming both ends of the produced λ/4 plate, a step of providing a protective layer on the surface of the λ/4 plate, and a step of performing a surface treatment such as a chemical treatment and a physical treatment on the surface of the λ/4 plate. The method for producing the λ/4 plate may also include a step that is the same as any step of the method for producing the λ/2 plate.

[6. Optional Layer]

The circularly polarizing plate may include an optional layer other than the aforementioned elements. Examples of the optional layer may include: a protective film for protecting the linear polarizer; an adhesive agent layer or a tackiness agent layer for bonding films to each other; a glass layer for suppressing scratches of a film; a hardcoat layer; an antireflective layer; an antifouling layer; and an optical compensation layer such as a positive C plate for suppressing a change in retardation caused when the circularly polarizing plate is observed from the tilt direction of the λ/4 plate. The positive C plate is an article wherein the retardation thereof in the front direction is 0, although the retardation varies in association with tilt direction such that changes in retardation of the λ/4 plate are canceled, and the refractive indices thereof satisfy the relationship of nx=ny<nz. Herein, the tilt direction of the λ/4 plate means a direction that is neither parallel nor perpendicular to the main surface of the λ/4 plate, and specifically indicates a direction within the range in which the polar angle of the main surface of the λ/4 plate is larger than 0° and smaller than 90°.

[7. Method of Producing Circularly Polarizing Plate]

The circularly polarizing plate may be produced by, for example, bonding the aforementioned linear polarizer, λ/2 plate, and λ/4 plate. An adhesive agent or a tackiness agent may be used for the bonding as necessary. Although the order of bonding may be any order, the circularly polarizing plate is usually obtained by bonding the λ/2 plate and the λ/4 plate to produce the broadband λ/4 plate, and thereafter bonding this broadband λ/4 plate and the linear polarizer.

A suitable example of the method for producing the circularly polarizing plate may include bonding the long-length linear polarizer having a polarized light absorption axis in the film lengthwise direction, the λ/2 plate having a slow axis which forms the orientation angle of the aforementioned angle α with respect to the film lengthwise direction, and the λ/4 plate having a slow axis which forms the orientation angle of the aforementioned angle β with respect to the film lengthwise direction, by roll-to-roll method with their film lengthwise directions in parallel to one another. According to such a production method, the circularly polarizing plate can be easily produced. The long-length circularly polarizing plate is usually cut out into a desired size, and provided to an image display device.

[8. Image Display Device]

The image display device according to the present invention includes an image display element and the aforementioned circularly polarizing plate provided on the visually recognizing side of the image display element. In this case, the circularly polarizing plate is provided to the image display device such that the linear polarizer, the λ/2 plate, and the λ/4 plate are disposed in this order from the image display element side.

Although there are various image display devices depending on the type of the image display element, representative examples thereof may include a liquid crystal display device including a liquid crystal cell as the image display element, and an organic electroluminescence display device including an organic electroluminescence element (hereinafter, sometimes appropriately referred to as an “organic EL element”) as the image display element.

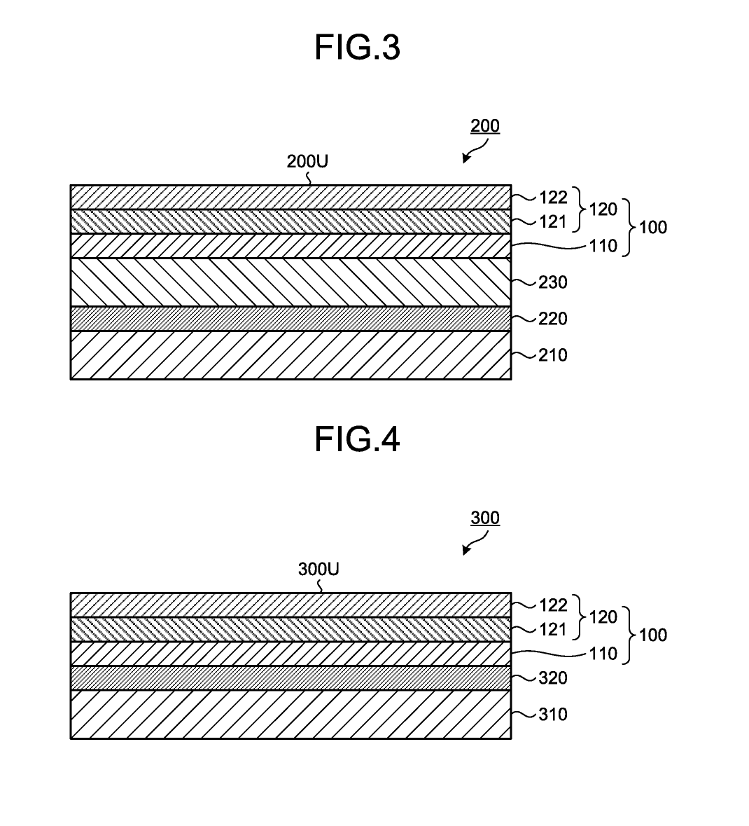

FIG. 3 is a cross-sectional view schematically illustrating an example of a liquid crystal display device 200 as an image display device according to an embodiment of the present invention.

As illustrated in FIG. 3, the liquid crystal display device 200 includes: a light source 210; a light source-side linear polarizer 220; a liquid crystal cell 230 as the image display element; and the circularly polarizing plate 100 including the linear polarizer 110 as a viewing-side linear polarizer, the λ/2 plate 121, and the λ/4 plate 122, in this order. Thus, the liquid crystal display device 200 includes the λ/4 plate 122, the λ/2 plate 121, the linear polarizer 110, the liquid crystal cell 230, the light source-side linear polarizer 220, and the light source 210, in this order from the visually recognizing side.

In the liquid crystal display device 200, an image is displayed by light which has been emitted from the light source 210 and passed through the light source-side linear polarizer 220, the liquid crystal cell 230, the linear polarizer 110, and the broadband λ/4 plate 120 including the λ/2 plate 121 and the λ/4 plate 122. The light to display an image is linearly polarized light when having passed through the linear polarizer 110, but is converted into circularly polarized light by passing through the broadband λ/4 plate 120. Thus, in the liquid crystal display device 200, an image is displayed by circularly polarized light. Accordingly, the image can be visually recognized when a display surface 200U is viewed through polarized sunglasses. At this time, the broadband λ/4 plate 120 converts linearly polarized light into circularly polarized light in a wide wavelength range. Therefore, changes in luminance and chromaticity due to a slant of polarized sunglasses can be suppressed, to thereby achieve favorable visibility. Further, since at least one of the λ/2 plate 121 and the λ/4 plate 122 includes the intermediate layer (not illustrated) containing an ultraviolet absorber, the broadband λ/4 plate 120 is excellent in light resistance and can suppress the coloring by light.

As the liquid crystal cell 230, for example, a liquid crystal cell in any mode such as an in-plane switching (IPS) mode, a vertical alignment (VA) mode, a multi-domain vertical alignment (MVA) mode, a continuous pinwheel alignment (CPA) mode, a hybrid alignment nematic (HAN) mode, a twisted nematic (TM) mode, a super twisted nematic (STN) mode, and an optical compensated bend (OCB) mode may be used.

FIG. 4 is a cross-sectional view schematically illustrating an example of an organic EL display device 300 as an image display device according to an embodiment of the present invention.

As illustrated in FIG. 4, the organic EL display device 300 includes, in this order, an organic EL element 310 as an image display element; a λ/4 plate 320; and a circularly polarizing plate 100 including a linear polarizer 110, a λ/2 plate 121, and a λ/4 plate 122. Therefore, the organic EL display device 300 includes the λ/4 plate 122, the λ/2 plate 121, the linear polarizer 110, the λ/4 plate 320, and the organic EL element 310 in this order from the visually recognizing side.

In the organic EL display device 300, the λ/4 plate 320 is usually provided for suppressing, by a combination with the linear polarizer 110, the glare of a display surface 300U due to the reflection of external light. Specifically, only linearly polarized light which is part of the light having entered from the outside of the device passes through the linear polarizer 110, and subsequently passes through the λ/4 plate 320 to become circularly polarized light. The circularly polarized light is reflected on a component (such as a reflective electrode (not illustrated) in the organic EL element 310) which reflects light in the display device. The light then passes through the λ/4 plate 320 again to become linearly polarized light having a vibration direction orthogonal to the vibration direction of the incident linearly polarized light, and thereby becomes unable to pass through the linear polarizer 110. Accordingly, the antireflection function is achieved (for the principle of antireflection in an organic EL display device, see Japanese Patent Application Laid-Open No. Hei. 9-127885 A). In the example illustrated in FIG. 4, the organic EL display device 300 includes a single member as the λ/4 plate 320. However, as the λ/4 plate 320, the broadband λ/4 plate including a combination of the λ/2 plate and the λ/4 plate may be used.

In the organic EL display device 300, an image is displayed by light which has been emitted from the organic EL element 310 and passed through the λ/4 plate 320, the linear polarizer 110, and the broadband λ/4 plate 120 including the λ/2 plate 121 and the λ/4 plate 122. Therefore, the light to display an image is linearly polarized light when having passed through the linear polarizer 110, but is converted into circularly polarized light by passing through the broadband λ/4 plate 120. Thus, in the organic EL display device 300, an image is displayed by circularly polarized light. Accordingly, the image can be visually recognized when the display surface 300U is viewed through polarized sunglasses. At this time, the broadband λ/4 plate 120 converts linearly polarized light into circularly polarized light in a wide wavelength range. Therefore, changes in luminance and chromaticity due to a slant of polarized sunglasses can be suppressed, to thereby achieve favorable visibility. Further, since at least one of the λ/2 plate 121 and the λ/4 plate 122 includes the intermediate layer (not illustrated) containing an ultraviolet absorber, the broadband λ/4 plate 120 is excellent in light resistance and can suppress the coloring by light.

The organic EL element 310 includes a transparent electrode layer, a light-emitting layer, and an electrode layer in this order. A voltage may be applied from the transparent electrode layer and the electrode layer so that the light-emitting layer generates light. Examples of a material constituting an organic light-emitting layer may include a polyparaphenylenevinylen-based material, a polyfluorene-based material, and a polyvinylcarbazole-based material. The light-emitting layer may be a layered body including a plurality of layers having different emission colors or a mixed layer obtained by doping a layer of a certain dye with a different dye. The organic EL element 310 may further include a functional layer such as a hole injection layer, a hole transport layer, an electron injection layer, an electron transport layer, an equipotential surface formation layer, and an electronic charge generation layer.

### EXAMPLE

Hereinafter, the present invention will be specifically described by illustrating Examples. However, the present invention is not limited to the Examples described below. The present invention may be optionally modified for implementation without departing from the scope of claims of the present invention and the scope of their equivalents. In the following description, “%” and “part” representing quantity are on the basis of weight, unless otherwise specified. The operation described below was performed under the conditions of normal temperature and normal pressure in the atmospheric air, unless otherwise specified.

In the following description “DCP” means tricyclo[4.3.0.1^{2,5}]deca-3-ene, “TCD” means tetracyclo[4.4.0.1^{2,5}.1^{7,10}]dodeca-3-ene, and “MTF” means tetracyclo[9.2.1.0^{2,10}.0^{3,8}]tetradeca-3,5,7,12-tetraene.

[Evaluation Method]

<Method for Measuring Orientation Angle θ of Film>

The direction of the slow axis of the film was measured using a phase difference meter (“KOBRA-21ADH” manufactured by Oji Scientific Instruments, Co. Ltd.), to thereby determine an orientation angle θ formed by the slow axis with respect to the film lengthwise direction.

<Method for Measuring In-Plane Retardation Re of Film>

The in-plane retardation of the film was measured at a measurement wavelength of 590 nm, using a phase difference meter (“KOBRA-21ADH” manufactured by Oji Scientific Instruments, Co. Ltd.).

<Method for Measuring Thickness of Each Layer Included in Film>

The thickness of the entire film was measured using a snap gauge.

The thickness of the intermediate layer included in the film was obtained by measuring the light transmittance at a wavelength of 390 nm of the film using a ultraviolet-visible-near-infrared spectrophotometer (“V-7200” manufactured by JASCO Corporation) and calculating the thickness from the obtained light transmittance. Further, since the first outer layer and the second outer layer were formed as layers having the same thickness in Examples and Comparative Examples described later, the total thickness of the first outer layer and the second outer layer was calculated by subtracting the thickness of the intermediate layer from the thickness of the entire film and dividing the obtained value by 2. When the first outer layer and the second outer layer are formed as layers having different thickness, the thickness of the first outer layer and the thickness of the second outer layer may be measured by observing the cross section of the film through a scanning electron microscope (SEM).

<Method for Measuring Light Transmittance>

The light transmittance at a wavelength of 380 nm and the light transmittance at a wavelength of 390 nm of the film were measured using an ultraviolet-visible-near-infrared spectrophotometer (“V-7200” manufactured by JASCO Corporation).

<Method for Evaluating Light Resistance>

The film was irradiated with light emitted from a xenon lamp with an irradiance of 60 W/m² for 500 hours. After that, the film was visually observed to evaluate the light resistance of the film according to the following criteria, on the basis of whether or not coloring was observed.

“Good”: No coloring was observed on the film after irradiation with light.

“Unacceptable”: Weak coloring was observed on the film after irradiation with light.

“Poor”: Strong coloring was observed on the film after irradiation with light.

<Method for Evaluating Image Visibility>

An organic EL display panel including an organic EL element was prepared. The circularly polarizing plate was mounted on the display surface of the organic EL display panel. The circularly polarizing plate was mounted in such a manner as the linear polarizer and the broadband λ/4 plate were disposed in this order from the organic EL element side. A white image was displayed on the organic EL display panel, and the display surface was visually observed from a front direction perpendicular to the display surface through polarized sunglasses worn by the observer. The observation was performed while the angle formed between the polarized light absorption axis of the polarized sunglasses and the polarized light absorption axis of the linear polarizer provided to the circularly polarizing plate was varied within the range of 0° to 360° by slanting the polarized sunglasses in such a manner that they rotated around a rotation axis perpendicular to the display surface. From the results of the observation, the visibility of an image by the circularly polarizing plate was evaluated on the basis of the following criteria.

“Good”: No change of toning was observed at every slant angle of polarized sunglasses.

“Poor”: A large change of toning was observed at every slant angle of polarized sunglasses.

### Production Example 1. Production of Resin J1

Into a reaction vessel in which the atmosphere had been substituted with nitrogen, 7 parts of a mixture of DCP, TCD, and MTF (DCP/TCD/MTF=55/40/5 weight ratio) and 1600 parts of cyclohexane were added. The amount of the mixture of DCP, TCD, and MTF is 1% by weight relative to the total amount of monomers used for polymerization. To the reaction vessel, 0.55 part of tri-i-butyl aluminum, 0.21 part of isobutyl alcohol, 0.84 part of diisopropyl ether as a reaction adjuster, and 3.24 parts of 1-hexene as a molecular weight adjuster were further added. To the resultant mixture, 24.1 parts of a 0.65% tungsten hexachloride solution containing cyclohexane as a solvent was added. The obtained solution was stirred at 55° C. for 10 minutes. Subsequently, while the reaction system was maintained at 55° C., 693 parts of a mixture of DCP, TCD, and MTF (DCP/TCD/MTF=55/40/5 weight ratio) and 48.9 parts of a 0.65% tungsten hexachloride solution containing cyclohexane as a solvent were each continuously dropped into the reaction system over 150 minutes. Thereafter, the reaction was continued for 30 minutes, and then the polymerization was terminated. Accordingly, a ring-opening polymerization reaction liquid containing a ring-opening polymer in cyclohexane was obtained. The polymerization conversion ratio measured by gas chromatography after the end of polymerization was 100%.

The obtained ring-opening polymerization reaction liquid was transferred into a pressure-resistant hydrogenation reaction vessel, and thereto 1.4 parts of a diatomaceous earth-supported nickel catalyst (“T8400RL” manufactured by Nikki Chemicals Co., nickel support ratio: 57%) and 167 parts of cyclohexane were added. Then, the reaction was performed at 180° C. with a hydrogen pressure of 4.6 MPa for 6 hours. By this hydrogenation reaction, a reaction solution containing a hydrogenated product of the ring-opening polymer was obtained. This reaction solution was filtered (“Fundabac Filter” manufactured by IHI corporation) under a pressure of 0.25 MPa with Radiolite #500 as a filtration bed to remove the hydrogenation catalyst. Thus, a colorless and transparent solution was obtained.

Subsequently, 0.5 part of an antioxidant (pentaerythritoltetrakis[3-(3,5-di-t-butyl-4-hydroxyphenyl)propionate], “Irganox 1010” manufactured by Ciba Specialty Chemicals Inc.) per 100 parts of the hydrogenated product was added to and dissolved in the obtained solution. Subsequently, filtration was sequentially performed with a Zeta Plus 30H filter (manufactured by Cuno Filter Co., Ltd., pore diameter: 0.5 μm to 1 μm), and further with another metal fiber filter (manufactured by Nichidai Corporation, pore diameter: 0.4 μm) to remove minute solid contents. The hydrogenation rate of the hydrogenated product of the ring-opening polymer was 99.9%.

Subsequently, the solution obtained by the aforementioned filtration was treated at a temperature of 270° C. with a pressure of 1 kPa or less using a cylindrical concentration dryer (manufactured by Hitachi, Ltd.) to remove the solvent cyclohexane and other volatile components from the solution. Then, the solid content in a melted state that had been contained in the solution was extruded into a strand shape from a die directly coupled to the concentrator. The extruded solid content was cooled to obtain a pellet of a resin J1 formed of the hydrogenated product of the ring-opening polymer. The hydrogenated product of the ring-opening polymer constituting the pellet had a weight-average molecular weight (Mw) of 38,000, a molecular weight distribution (Mw/Mn) of 2.5, and a glass transition temperature Tg of 126° C.

### Production Example 2. Production of Resin J2

Using a twin screw extruder, 100 parts of a dried polymer containing an alicyclic structure (manufactured by ZEON Corporation, glass transition temperature: 126° C.) and 7.0 parts of a benzotriazole-based ultraviolet absorber (“LA-31” manufactured by ADEKA Corporation) were mixed. Subsequently, the mixture was poured in a hopper connected to the extruder, and supplied to a single screw extruder to perform melt-extrusion. Thus, a rein J2 was obtained. The content of the ultraviolet absorber in the resin J2 was 7.0% by weight.

### Production Example 3. Production of Resin J3

A resin J3 containing 12.0% by weight of an ultraviolet absorber was produced in the same manner as that in Production Example 2 except that the amount of the benzotriazole-based ultraviolet absorber relative to 100 parts of the polymer containing an alicyclic structure was changed to 12.0 parts.

### Production Example 4. Production of Resin J4

A polymer containing an alicyclic structure (“ZEONOR1600” manufactured by ZEON Corporation, glass transition temperature: 163° C.) was prepared as a resin J4.

### Production Example 5. Production of Resin J5

A resin J5 containing 9.0% by weight of an ultraviolet absorber was produced in the same manner as that in Production Example 2 except that the amount of the benzotriazole-based ultraviolet absorber relative to 100 parts of the polymer containing an alicyclic structure was changed to 9.0 parts.

### Production Example 6. Production of λ/2 Plate H1 for Example 1

(Production of Pre-Stretch Film)

A double flight-type single screw extruder (screw diameter: D=50 mm, ratio between screw effective length L and screw diameter D L/D=32) equipped with a leaf disc-shaped polymer filter having openings of 3 μm was prepared. The resin J2 as a resin for the intermediate layer was introduced to this single screw extruder, and melted. The melted resin was supplied to a multi-manifold die having a die lip surface roughness Ra of 0.1 μm under the conditions of an extruder outlet temperature of 280° C. and an extruder gear pump rotational speed of 10 rpm.

Meanwhile, a single screw extruder (screw diameter: D=50 mm, ratio between screw length L and screw diameter D L/D=32) equipped with a leaf disc-shaped polymer filter having openings of 3 μm was prepared. The resin J1 was introduced as a resin for the first outer layer and the second outer layer into the single screw extruder, and melted. The melted resin was supplied to the aforementioned multi-manifold die under the conditions of an extruder outlet temperature of 285° C. and an extruder gear pump rotational speed of 4 rpm.

Subsequently, the resins J1 and J2 were co-extruded from the multi-manifold die at 280° C. so as to be discharged in a film shape containing three layers of: a layer of the resin for forming the first outer layer; a layer of the resin for forming the intermediate layer; and a layer of the resin for forming the second outer layer. The discharged resins J1 and J2 were cast on a cooling roll of which the temperature was adjusted at 150° C. to obtain a pre-stretch film with a width of 1450 mm and a thickness of 65 μm formed of three layers of the first outer layer (thickness: 1 μm) formed of the resin J1/the intermediate layer (thickness: 63 μm) formed of the resin J2/the second outer layer (thickness: 1 μm) formed of the resin J1. During the aforementioned co-extrusion, the air gap amount was 50 mm. As the method for casting the melted film-shaped resin on the cooling roll, edge pinning was adopted. Both ends in the film widthwise direction of the pre-stretch film obtained in this manner were each trimmed by 50 mm to adjust the width to 1350 mm.

(Oblique Stretching)

While the aforementioned pre-stretch film was continuously conveyed in the lengthwise direction, the pre-stretch film was subjected to the oblique stretching treatment of performing stretching in an oblique direction at a stretch temperature of 130° C. and a stretching ratio of 1.7 times using a tenter stretching machine equipped with grippers for gripping the ends of the film. Thus, an intermediate film was obtained. The orientation angle θ, the in-plane retardation Re, and the thickness of each layer of the obtained intermediate film were measured.

(Longitudinal Stretching)

While the aforementioned intermediate film was continuously conveyed in the lengthwise direction, the intermediate film was subjected to the longitudinal stretching treatment of performing stretching in a film lengthwise direction at a stretch temperature of 125° C. and a stretching ratio of 1.5 times. Accordingly, a long-length λ/2 plate H1 was obtained. The orientation angle θ, the in-plane retardation Re, and the thickness of each layer of the obtained λ/2 plate H1 were measured.

### Production Examples 7 to 10. Production of λ/2 Plates H2 to H5 for Examples 2 to 5

The type of the resin for forming the intermediate layer; the thicknesses of the intermediate layer, the first outer layer, and the second outer layer; the stretching conditions for the oblique stretching treatment; and the stretching conditions for the longitudinal stretching treatment were changed as shown in Table 1. The production and evaluation for λ/2 plates H2 to H5 were performed in the same manner as that of Production Example 6 except for the aforementioned matters.

### Production Example 11. Production of λ/2 Plate H6 for Comparative Example 2

(Production of Pre-Stretch Film)

A double flight-type single screw extruder (screw diameter: D=50 mm, ratio between screw effective length L and screw diameter D L/D=32) equipped with a leaf disc-shaped polymer filter having openings of 3 μm was prepared. The resin J1 was introduced to this single screw extruder to be melted, and was supplied to a single layer die having a die lip surface roughness Ra of 0.1 μm under the conditions of an extruder outlet temperature of 280° C. and an extruder gear pump rotational speed of 10 rpm.

Subsequently, the resin J1 was extruded from the single layer die at 280° C. The extruded resin J1 was cast on a cooling roll of which the temperature was adjusted at 150° C. to obtain a pre-stretch film with a width of 1450 mm and a thickness of 70 μm formed of the resin J1. During the aforementioned co-extrusion, the air gap amount was 50 mm. As the method for casting the melted film-shaped resin on the cooling roll, edge pinning was adopted. Both ends in the film widthwise direction of the pre-stretch film obtained in this manner were each trimmed by 50 mm to adjust the width to 1350 mm.

(Oblique Stretching)

While the aforementioned pre-stretch film was continuously conveyed in the lengthwise direction, the pre-stretch film was subjected to the oblique stretching treatment of performing stretching in an oblique direction at a stretch temperature of 133° C. and a stretching ratio of 1.47 times using a tenter stretching machine equipped with grippers for gripping the ends of the film. Thus, an intermediate film was obtained. The orientation angle θ, the in-plane retardation Re, and the thickness of each layer of the obtained intermediate film were measured.

(Longitudinal Stretching)

While the aforementioned intermediate film was continuously conveyed in the lengthwise direction, the intermediate film was subjected to the longitudinal stretching treatment of performing stretching in a film lengthwise direction at a stretch temperature of 125° C. and a stretching ratio of 1.4 times. Accordingly, a long-length λ/2 plate H6 was obtained. The orientation angle θ, the in-plane retardation Re, and the thickness of each layer of the obtained λ/2 plate H6 were measured.

### Production Example 12. Production of λ/2 Plate H7 for Comparative Example 3

The type of the resin for forming the intermediate layer; the thicknesses of the intermediate layer, the first outer layer, and the second outer layer; the stretching conditions for the oblique stretching treatment; and the stretching conditions for the longitudinal stretching treatment were changed as shown in Table 1. The production and evaluation for λ/2 plate H7 were performed in the same manner as that of Production Example 6 except for the aforementioned matters.

### Production Example 13. Production of λ/4 Plate Q1 for Example 1

(Production of Pre-Stretch Film)

A double flight-type single screw extruder (screw diameter: D=50 mm, ratio between screw effective length L and screw diameter D L/D=32) equipped with a leaf disc-shaped polymer filter having openings of 3 μm was prepared. The resin J2 as a resin for the intermediate layer was introduced to this single screw extruder, and melted. The melted resin was supplied to a multi-manifold die having a die lip surface roughness Ra of 0.1 μm under the conditions of an extruder outlet temperature of 280° C. and an extruder gear pump rotational speed of 10 rpm.

Meanwhile, a single screw extruder (screw diameter: D=50 mm, ratio between screw length L and screw diameter D L/D=32) equipped with a leaf disc-shaped polymer filter having openings of 3 μm was prepared. The resin J1 was introduced as a resin for the first outer layer and the second outer layer into the single screw extruder, and melted. The melted resin was supplied to the aforementioned multi-manifold die under the conditions of an extruder outlet temperature of 285° C. and an extruder gear pump rotational speed of 4 rpm.

Subsequently, the resins J1 and J2 were co-extruded from the multi-manifold die at 280° C. so as to be discharged in a film shape containing three layers of: a layer of the resin for forming the first outer layer; a layer of the resin for forming the intermediate layer; and a layer of the resin for forming the second outer layer. The discharged resins J1 and J2 were cast on a cooling roll of which the temperature was adjusted at 150° C. to obtain a pre-stretch film with a width of 1450 mm and a thickness of 85 μm formed of three layers of the first outer layer (thickness: 2.5 μm) formed of the resin J1/the intermediate layer (thickness: 80 μm) formed of the resin J2/the second outer layer (thickness: 2.5 μm) formed of the resin J1. During the aforementioned co-extrusion, the air gap amount was 50 mm. As the method for casting the melted film-shaped resin on the cooling roll, edge pinning was adopted. Both ends in the film widthwise direction of the pre-stretch film obtained in this manner were each trimmed by 50 mm to adjust the width to 1350 mm.

(Oblique Stretching)

While the aforementioned pre-stretch film was continuously conveyed in the lengthwise direction, the pre-stretch film was subjected to the oblique stretching treatment of performing stretching in an oblique direction at a stretch temperature of 136° C. and a stretching ratio of 4.7 times using a tenter stretching machine equipped with grippers for gripping the ends of the film. Thus, a long-length λ/4 plate Q1 was obtained. The orientation angle θ, the in-plane retardation Re, and the thickness of each layer of the obtained λ/4 plate Q1 were measured.

### Production Examples 14 to 17. Production of λ/2 Plates Q2 to Q5 for Examples 2 to 5 and Comparative Example 1

The type of the resin for forming the intermediate layer; the thicknesses of the intermediate layer, the first outer layer, and the second outer layer; and the stretching conditions for the oblique stretching treatment were changed as shown in Table 2. The production and evaluation for λ/4 plates Q2 to Q5 were performed in the same manner as that of Production Example 13 except for the aforementioned matters.

### Production Example 18. Production of λ/4 Plate Q6 for Comparative Example 2

(Production of Pre-Stretch Film)

A double flight-type single screw extruder (screw diameter: D=50 mm, ratio between screw effective length L and screw diameter D=L/D 32) equipped with a leaf disc-shaped polymer filter having openings of 3 μm was prepared. The resin J1 was introduced to this single screw extruder to be melted, and was supplied to a single layer die having a die lip surface roughness Ra of 0.1 μm under the conditions of an extruder outlet temperature of 280° C. and an extruder gear pump rotational speed of 10 rpm.

Subsequently, the resin J1 was extruded from the single layer die at 280° C. The extruded resin J1 was cast on a cooling roll of which the temperature was adjusted at 150° C. to obtain a pre-stretch film with a width of 1450 mm and a thickness of 80 μm formed of the resin J1. During the aforementioned co-extrusion, the air gap amount was 50 mm. As the method for casting the melted film-shaped resin on the cooling roll, edge pinning was adopted. Both ends in the film widthwise direction of the pre-stretch film obtained in this manner were each trimmed by 50 mm to adjust the width to 1350 mm.

(Oblique Stretching)

While the aforementioned pre-stretch film was continuously conveyed in the lengthwise direction, the pre-stretch film was subjected to the oblique stretching treatment of performing stretching in an oblique direction at a stretch temperature of 180° C. and a stretching ratio of 4.7 times using a tenter stretching machine equipped with grippers for gripping the ends of the film. Thus, a λ/4 plate Q6 was obtained. The orientation angle θ, the in-plane retardation Re, and the thickness of each layer of the obtained λ/4 plate Q6 were measured.

### Production Example 19. Production of λ/2 Plate Q7 for Comparative Example 3

The type of the resin for forming the intermediate layer; the thicknesses of the intermediate layer, the first outer layer, and the second outer layer; and the stretching conditions of the oblique stretching treatment were changed as shown in Table 2. The production and evaluation for λ/4 plate Q7 were performed in the same manner as that of Production Example 13 except for the aforementioned matters.

### Example 1

(Production of Broadband λ/4 Plate)

The λ/2 plate H1 and the λ/4 plate Q1 were bonded through a tackiness agent (“CS9621” manufactured by Nitto Denko Corporation) with their film lengthwise directions in parallel to each other, in such a manner that the slow axis of the λ/2 plate H1 and the slow axis of the λ/4 plate Q1 intersect at 60°. Thus, a long-length broadband λ/4 plate was produced. The light transmittance at a wavelength of 380 nm and the light transmittance at a wavelength of 390 nm of the obtained broadband λ/4 plate were measured by the aforementioned method. Also, the light resistance of the broadband λ/4 plate was evaluated by the aforementioned method.

(Production of Circularly Polarizing Plate)

The surface on the λ/2 plate side of the broadband λ/4 plate was subjected to a corona treatment. The surface of the broadband λ/4 plate having been subjected to the corona treatment and one surface of a long-length polarizing film (“HLC2-5618S” manufactured by Sanritz Corporation, thickness: 180 μm, having a transmission axis in the direction of 0° with respect to the widthwise direction) as a linear polarizer were bonded through a tackiness and adhesive agent (LE-3000 series; manufactured by Hitachi Chemical Co., Ltd.). The bonding was performed with the film lengthwise direction of the broadband λ/4 plate and the film lengthwise direction of the polarizing film in parallel to each other, in such a manner that the slow axis of the λ/2 plate and the polarized light absorption axis of the polarizing film form an angle of 15° when seen from the thickness direction. After that, the tackiness adhesive agent was irradiated with ultraviolet light through the polarizing film for curing. Accordingly, a circularly polarizing plate including the linear polarizer, the λ/2 plate, and the λ/4 plate in this order was obtained. The obtained circularly polarizing plate was mounted on an organic EL display panel, and evaluated for image visibility by the aforementioned method.

### Examples 2 to 5

A broadband λ/4 plate and a circularly polarizing plate were produced and evaluated in the same manner as that of Example 1, except that the λ/2 plate and the λ/4 plate to be used were changed as shown in Table 3.

### Comparative Example 1

The light transmittance at a wavelength of 380 nm and the light transmittance at a wavelength of 390 nm of the λ/4 plate Q5 were measured by the aforementioned method. Also, the light resistance of the λ/4 plate Q5 was evaluated by the aforementioned method.

One surface of the λ/4 plate Q5 was subjected to a corona treatment. The surface of the λ/4 plate Q5 having been subjected to the corona treatment and one surface of a long-length polarizing film (“HLC2-5618S” manufactured by Sanritz Corporation, thickness: 180 μm, having a transmission axis in the direction of 0° with respect to the widthwise direction) as the linear polarizer were bonded through a tackiness and adhesive agent (LE-3000series; manufactured by Hitachi Chemical Co., Ltd.). The bonding was performed in such a manner that the slow axis of the λ/4 plate Q5 and the polarized light absorption axis of the polarizing film form an angle of 45° when seen from the thickness direction. After that, the tackiness adhesive agent was irradiated with ultraviolet light through the polarizing film for curing. Accordingly, a circularly polarizing plate including the linear polarizer and the λ/4 plate in this order was obtained. The obtained circularly polarizing plate was mounted on an organic EL display panel, and evaluated for image visibility by the aforementioned method.

### Comparative Examples 2 and 3

A broadband λ/4 plate and a circularly polarizing plate were produced and evaluated in the same manner as that of Example 1, except that the λ/2 plate and the λ/4 plate to be used were changed as shown in Table 3.

[Result]

The production conditions and configuration of each of the λ/2 plates H1 to H7 produced in Production Examples 6 to 12 are shown in the following Table 1. Also, the production conditions and configuration of each of the λ/4 plates Q1 to Q7 produced in Production Examples 13 to 19 are shown in the following Table 2. Furthermore, the results of Examples 1 to 5 and Comparative Examples 1 to 3 are shown in the following Table 3.

In the following Tables, the abbreviations mean as follows.

“UVA Concentration”: The concentration of the ultraviolet absorber in the intermediate layer.

“Outer layer thickness”: The thickness of each of the first outer layer and the second outer layer.

“Re”: In-plane retardation.

“Orientation angle θ”: The angle formed by the slow axis with respect to the film lengthwise direction. Upon forming a circularly polarizing plate, the angle becomes an angle formed by the slow axis with respect to the polarized light absorption axis of the linear polarizer.

TABLE 1
[λ/2 plate production conditions and configuration]

| | Prod. | Prod. | Prod. | Prod. | Prod. | Prod. | Prod. |
|---|---|---|---|---|---|---|---|
| | Ex. 6 | Ex. 7 | Ex. 8 | Ex. 9 | Ex. 10 | Ex. 11 | Ex. 12 |
| | H1 | H2 | H3 | H4 | H5 | H6 | H7 |
| Pre-stretch film | | | | | | | |
| First outer layer resin | J1 | J1 | J1 | J1 | J1 | — | J1 |
| Intermediate layer resin | J2 | J2 | J2 | J3 | J3 | J1 | J5 |
| Second outer layer resin | J1 | J1 | J1 | J1 | J1 | — | J1 |
| UVA concentration (%) | 7 | 7 | 7 | 12 | 12 | 0 | 9 |
| Total thickness (μm) | 65 | 70 | 88 | 75 | 75 | 70 | 75 |
| Intermediate layer thickness (μm) | 63 | 68 | 84 | 73 | 73 | — | 50 |
| Outer layer thickness (μm) | 1 | 1 | 2 | 1 | 1 | — | 12.5 |
| Layer ratio (outer:intermediate) | 1:63 | 1:68 | 1:42 | 1:73 | 1:73 | — | 1:4 |
| Intermediate film | | | | | | | |
| Stretching method | Oblique | Oblique | Oblique | Oblique | Oblique | Oblique | Oblique |
| Ratio (times) | 1.7 | 1.6 | 1.7 | 1.7 | 1.7 | 1.47 | 2 |
| Temperature (° C.) | 130 | 133 | 136 | 131 | 131 | 133 | 131 |
| Re(nm) | 220 | 220 | 220 | 220 | 220 | 195 | 220 |
| Orientation angle θ (°) | 45 | 45 | 20 | 45 | 45 | 45 | 45 |
| Total thickness (μm) | 38.2 | 44.0 | 51.8 | 44.1 | 44.1 | 47.6 | 37.5 |
| Intermediate layer thickness (μm) | 37.1 | 42.8 | 49.4 | 42.9 | 42.9 | — | 25.0 |
| Outer layer thickness (μm) | 0.6 | 0.6 | 1.2 | 0.6 | 0.6 | — | 6.3 |
| λ/2 plate | | | | | | | |
| Stretching method | Longi- | Longi- | Longi- | Longi- | Longi- | Longi- | Longi- |
| | tudinal | tudinal | tudinal | tudinal | tudinal | tudinal | tudinal |
| Ratio (times) | 1.5 | 1.5 | 1.5 | 1.5 | 1.5 | 1.4 | 1.6 |
| Temperature (° C.) | 125 | 126 | 128 | 125 | 125 | 125 | 126 |
| Re(nm) | 245 | 245 | 245 | 245 | 245 | 245 | 245 |
| Orientation angle θ (°) | 75 | 75 | 75 | 75 | 75 | 75 | 75 |
| Total thickness (μm) | 31.2 | 35.9 | 42.3 | 36.0 | 36.0 | 40.2 | 29.6 |
| Intermediate layer thickness (μm) | 30.3 | 34.9 | 40.3 | 35.1 | 35.1 | — | 19.8 |
| Outer layer thickness (μm) | 0.5 | 0.5 | 1.0 | 0.5 | 0.5 | — | 4.9 |

TABLE 2
[λ/4 plate production conditions and configuration]

| | Prod. | Prod. | Prod. | Prod. | Prod. | Prod. | Prod. |
|---|---|---|---|---|---|---|---|
| | Ex. 13 | Ex. 14 | Ex. 15 | Ex. 16 | Ex. 17 | Ex. 18 | Ex. 19 |
| | Q1 | Q2 | Q3 | Q4 | Q5 | Q6 | Q7 |
| Pre-stretch film | | | | | | | |
| First outer layer | J1 | J1 | J1 | J1 | J1 | — | J1 |
| Intermediate layer | J2 | J2 | J4 | J4 | J2 | J1 | J5 |
| Second outer layer | J1 | J1 | J1 | J1 | J1 | — | J1 |
| UVA concentration(%) | 7 | 7 | 0 | 0 | 7 | 0 | 9 |
| Total thickness (μm) | 85 | 90 | 104 | 65 | 70 | 80 | 85 |
| Intermediate layer thickness (μm) | 80 | 85 | 100 | 61 | 35 | — | 38 |
| Outer layer thickness (μm) | 2.5 | 2.5 | 2 | 2 | 17.5 | — | 23.5 |
| Layer ratio (outer:intermediate) | 1:32 | 1:34 | 1:50 | 1:31 | 1:2 | — | 1:2 |
| λ/4 plate | | | | | | | |
| Stretching method | Oblique | Oblique | Oblique | Oblique | Oblique | Oblique | Oblique |
| Ratio (times) | 4.7 | 4.7 | 2.0 | 3.6 | 1.47 | 4.7 | 4.7 |
| Temperature (° C.) | 136 | 136 | 180 | 190 | 140 | 180 | 138 |
| Re(nm) | 122 | 122 | 122 | 122 | 100 | 122 | 122 |
| Orientation angle θ (°) | 15 | 15 | 15 | 15 | 45 | 15 | 15 |
| Total thickness (μm) | 18.1 | 19.1 | 52.0 | 18.1 | 47.6 | 17.0 | 18.1 |
| Intermediate layer thickness (μm) | 17.0 | 18.1 | 50.0 | 17.0 | 23.8 | — | 8.1 |
| Outer layer thickness (μm) | 0.5 | 0.5 | 1.0 | 0.5 | 11.9 | — | 5.0 |

TABLE 3
[Results of Examples and Comparative Examples]

| | | | | | | Comp. | Comp. | Comp. |
|---|---|---|---|---|---|---|---|---|
| | Ex. 1 | Ex. 2 | Ex. 3 | Ex. 4 | Ex. 5 | Ex. 1 | Ex. 2 | Ex. 3 |
| λ/2 plate | H1 | H2 | H3 | H4 | H5 | — | H6 | H7 |
| UVA concentration (%) | 7% | 7% | 7% | 12% | 12% | — | 0% | 9% |
| Intermediate layer thickness (μm) | 30 | 35 | 40 | 35 | 35 | — | 40 | 20 |
| Outer layer thickness (μm) | 0.5 | 0.5 | 1 | 0.5 | 0.5 | — | 0 | 5 |
| Re(nm) | 245 | 245 | 245 | 245 | 245 | — | 245 | 245 |
| Orientation angle θ | 15.0° | 15.0° | 15.0° | 15.0° | 15.0° | — | 15.0° | 15.0° |
| λ/4 plate | Q1 | Q2 | Q2 | Q3 | Q4 | Q5 | Q6 | Q7 |
| UVA concentration (%) | 7% | 7% | 7% | 0% | 0% | 7% | 0% | 9% |
| Intermediate layer thickness (μm) | 17 | 18 | 18 | 50 | 18 | 24 | 17 | 8 |
| Outer layer thickness (μm) | 0.5 | 0.5 | 0.5 | 1 | 0.5 | 12 | 0 | 5 |
| Re(nm) | 122 | 122 | 122 | 122 | 122 | 100 | 122 | 122 |
| Orientation angle θ | 75.0° | 75.0° | 75.0° | 75.0° | 75.0° | 45.0° | 75.0° | 75.0° |
| 380 nm transmittance | 0.1% | 0.0% | 0.0% | 0.2% | 0.2% | 0.0% | 90.0% | 0.1% |
| 390 nm transmittance | 3.0% | 2.0% | 1.0% | 2.0% | 2.0% | 12.0% | 92.0% | 6.5% |
| Light resistance | Good | Good | Good | Good | Good | Unacceptable | Poor | Unacceptable |
| Image visibility | Good | Good | Good | Good | Good | Poor | Good | Good |

[Discussion]

In Comparative Example 1 in which the circularly polarizing plate that does not include the broadband λ/4 plate, the evaluation result was poor in image visibility, and inferior in visibility through polarized sunglasses.

Also, in Comparative Example 2 in which both the λ/2 plate and the λ/4 plate of the broadband λ/4 plate do not include the intermediate layer containing an ultraviolet absorber, the broadband λ/4 plate has inferior light resistance, and coloring due to irradiation with light is caused. Furthermore, even in Comparative Example 3 in which the λ/2 plate and the λ/4 plate have the intermediate layer containing an ultraviolet absorber, the light transmittance at an wavelength of 390 nm of the broadband λ/4 plate is high, with the result that the broadband λ/4 plate is inferior in light resistance.

In contrast to them, in Examples 1 to 5, excellent results are obtained for both light resistance and visibility. As confirmed from these results, according to the present invention, there can be achieved a circularly polarizing plate which includes a broadband λ/4 plate having excellent light resistance and which can improve the visibility of an image viewed through polarized sunglasses.

### REFERENCE SIGN LIST

100 circularly polarizing plate
110 linear polarizer
120 broadband λ/4 plate
121 λ/2 plate
122 λ/4 plate
200 liquid crystal display device
210 light source
220 light source-side linear polarizer
230 liquid crystal cell
300 organic EL display device
310 organic EL element
320 λ/4 plate

1. A circularly polarizing plate for disposing in an image display device having an image display element, the circularly polarizing plate being disposed on a visually recognizing side of the image display element,
the circularly polarizing plate comprising a linear polarizer and a broadband λ/4 plate in this order from a side of the image display element, wherein
the broadband λ/4 plate includes a λ/2 plate and a λ/4 plate in this order from a side of the linear polarizer,
at least one of the λ/2 plate and the λ/4 plate is a multilayer body including a first outer layer, an intermediate layer containing an ultraviolet absorber, and a second outer layer in this order,
the broadband λ/4 plate has a light transmittance of 1.0% or less at a wavelength of 380 nm, and
the broadband λ/4 plate has a light transmittance of 5.0% or less at a wavelength of 390 nm.

2. The circularly polarizing plate according to claim 1, wherein
the λ/2 plate has a thickness of 25 μm or more and 45 μm or less,
the λ/4 plate has a thickness of 10 μm or more and 60 μm or less, and
a total thickness of the λ/2 plate and the λ/4 plate is 100 μm or less.

3. The circularly polarizing plate according to claim 1, wherein a ratio of “thickness of the intermediate layer”/“thickness of the multilayer body” is ⅓ to 80/82.

4. The circularly polarizing plate according to claim 1, wherein
the intermediate layer is formed of a thermoplastic resin containing the ultraviolet absorber, and
the thermoplastic resin contains the ultraviolet absorber in an amount of 3% by weight to 20% by weight.

5. The circularly polarizing plate according to claim 1, an angle formed by a slow axis of the λ/4 plate with respect to the polarized light absorption axis of the linear polarizer being (2α+45°)±5°,
wherein α is an angle formed by a slow axis of the λ/2 plate with respect to a polarized light absorption axis of the linear polarizer.

6. The circularly polarizing plate according to claim 1, wherein an angle α formed by the slow axis of the λ/2 plate with respect to the polarized light absorption axis of the linear polarizer is 15°±5°.

7. The circularly polarizing plate according to claim 1, wherein the λ/4 plate is an obliquely stretched film.

8. The circularly polarizing plate according to claim 1, wherein the λ/2 plate is a sequentially biaxially stretched film.

9. An image display device comprising an image display element, and the circularly polarizing plate according to claim 1, the circularly polarizing plate being disposed on the visually recognizing side of the image display element.

10. The image display device according to claim 9, wherein the image display element is a liquid crystal cell or an organic electroluminescence element.
